(19) United States
(12) Patent Application Publication
(10) Pub. No.: US 2024/0113252 A1
(43) Pub. Date: Apr. 4, 2024

(54) APPARATUS FOR TRANSFERRING LIGHT EMITTING ELEMENTS AND TRANSFER METHOD USING THE APPARATUS

(71) Applicant: Samsung Display Co., LTD., Yongin-si (KR)

(72) Inventors: Jeong Won HAN, Yongin-si (KR); Won Hee OH, Yongin-si (KR)

(21) Appl. No.: 18/464,038

(22) Filed: Sep. 8, 2023

(30) Foreign Application Priority Data
Oct. 4, 2022 (KR) 10-2022-0126152

(51) Int. Cl. H01L 33/00

(52) U.S. Cl. CPC H01L 33/0075

(57) ABSTRACT

An apparatus for transferring light emitting elements includes: a transfer member including a stamp layer having an adhesive property and a base layer on a first surface of the stamp layer, the transfer member having a transfer portion, a folding portion, and an incision groove at a boundary between the transfer portion and the folding portion; a protective film on a second surface of the stamp layer, the protective film having an incision groove defining a transfer area and a folding area; an inversion member supporting the transfer member; and a transfer head including a chuck configured to adsorb to the base layer and to move the transfer member vertically and horizontally. The transfer portion is at a center with respect to the incision groove, and the folding portion is at an outer side of the incision groove with respect to the transfer portion.

### CROSS-REFERENCE TO RELATED APPLICATION

This application claims priority to and the benefit of Korean Patent Application No. 10-2022-0126152, filed on Oct. 4, 2022, in the Korean Intellectual Property Office, the entire disclosure of which is incorporated herein by reference.

### BACKGROUND

### 1. Field

Aspects of embodiments of the present disclosure relate to an apparatus for transferring light emitting elements and a transfer method using the apparatus.

### 2. Description of the Related Art

Display devices are becoming increasingly important with the development and popularity of multimedia. Accordingly, various types of display devices, such as organic light emitting displays and liquid crystal displays, are being used.

A display device includes a display panel, such as an organic light emitting display panel or a liquid crystal display panel, as a device for displaying an image of the display device. From among the types of display panels, a light emitting display panel may include light emitting diodes. The light emitting diodes may be organic light emitting diodes using an organic material as a fluorescent material or may be inorganic light emitting diodes using an inorganic material as a fluorescent material.

Manufacturing apparatuses and methods for placing micro-light emitting diodes on a substrate of the display panel should be developed to manufacture a display panel using inorganic light emitting diodes as light emitting diodes.

### SUMMARY

Embodiments of the present disclosure provide an apparatus for transferring light emitting elements without needing to consider contamination of a transfer member by transferring light emitting elements on a donor substrate to a circuit board using a disposable transfer member.

Embodiments of the present disclosure also provide a transfer member having a folding portion to prevent a head chuck of a transfer head from being contaminated during a transfer process.

Embodiments of the present disclosure also provide an apparatus for transferring light emitting elements in which a fixing force between a transfer head and a transfer member is greater than a fixing force between light emitting elements and a substrate in (or during) a process of transferring the light emitting elements by using the transfer member.

However, aspects and features of the present disclosure are not limited to those described herein. The above and other aspects and features of the present disclosure will become more apparent to one of ordinary skill in the art to which the present disclosure pertains by referencing the detailed description of the present disclosure below.

According to an embodiment of the present disclosure, an apparatus for transferring light emitting elements is provided. The apparatus includes: a transfer member including a stamp layer having an adhesive property and a base layer on a first surface of the stamp layer, the transfer member having a transfer portion, a folding portion, and an incision groove at a boundary between the transfer portion and the folding portion; a protective film on a second surface of the stamp layer, the protective film having an incision groove defining a transfer area and a folding area; an inversion member supporting the transfer member; and a transfer head including a chuck configured to adsorb to the base layer and to move the transfer member vertically and horizontally. The transfer portion is at a center with respect to the incision groove, and the folding portion is at an outer side of the incision groove with respect to the transfer portion.

The inversion member may include: a support chuck configured to adsorb to the protective film at an area overlapping the transfer portion; and a vertical movement unit neighboring the support chuck and configured to move up and down.

The transfer portion of the transfer member may overlap the support chuck, and the folding portion of the transfer member may overlap the vertical movement unit. The folding portion may be folded about the incision groove by rising of the vertical movement unit.

The transfer head may include: a body; a head chuck in a center of the body and configured to adsorbed to the transfer portion of the transfer member; and a clamp movable between an edge of the body and the head chuck and configured to fix the folding portion.

The head chuck may have a surface equal to or smaller than the transfer area. The folding portion of the transfer member may cover at least three surfaces of the head chuck.

According to another embodiment of the present disclosure, an apparatus for transferring light emitting elements is provided. The apparatus includes: a transfer member including a stamp layer having an adhesive property and a base layer on a first surface of the stamp layer, the transfer member having an incision groove, a transfer portion at an inner side of the incision groove, and a folding portion at an outer side of the incision groove; a protective film on a second surface of the stamp layer, the protective film having an incision groove defining a transfer area and a folding area; a transfer head having a chuck configured to be adsorbed to the base layer and to move the transfer member vertically and horizontally; and a folding member including a detachable clamp, the clamp being configured to maintain the folding portion of the transfer member folded by fixing the folding portion of the transfer member.

The folding member may include: a clamp support portion having a central groove in which the transfer portion of the transfer member is to be placed; and a clamp fixing portion around the central groove. The clamp may be detachably on the clamp fixing portion.

The folding member may further include a movable support portion configured to move the clamp outwardly from the central groove according to a size of the transfer member.

The clamp may be attached to the clamp fixing portion to guide the transfer member to the central groove and may become narrower toward the bottom so that the folding portion is folded when the transfer member is placed in the central groove.

The transfer head may include: a body; a head chuck in a center of the body and configured to be adsorbed to the transfer portion of the transfer member; and a movable fixing portion movable between an edge of the body and the head chuck and configured to fix the folding portion.

The apparatus may further include light emitting elements, and the light emitting elements may include an n-type semiconductor, an active layer, a p-type semiconductor, a first contact electrode, and a second contact electrode.

According to another embodiment of the present disclosure, a method of transferring light emitting elements is provided. The method includes: placing a transfer member ledger having a protective film on a support member; cutting the transfer member ledger to a size of a transfer unit to form transfer members and forming an incision groove in the protective film to define a folding area and a transfer area in each of the transfer members; vertically and horizontally inverting a plurality of transfer members by using an inversion member and folding a transfer member of the folding area; fixing and lifting the folded transfer member by using a transfer head and peeling off the protective film of a transfer portion; detaching light emitting elements from a donor substrate by attaching the light emitting elements to the transfer member of the transfer area and lifting the transfer member by using the transfer head; and aligning the light emitting elements on a circuit board by using the transfer head and detaching the transfer member from the transfer head.

The method may further include: bonding the light emitting elements, which are attached to the transfer member, onto the circuit board; and peeling and removing the transfer member from the light emitting elements bonded to the circuit board by using the transfer head.

Each of the transfer members may include a base layer and a stamp layer on a surface of the base layer, and the stamp layer may be made of an adhesive material.

In the placing of the transfer member ledger, the base layer, the stamp layer, and the protective film may be sequentially on the support member. In the placing of the transfer member ledger, the transfer member ledger may be provided in a roll-to-roll type or a sheet type.

The circuit board may include a flux applied to a surface thereof. The flux may be removed from the circuit board by a flux cleaning agent after the peeling and removing of the transfer member from the light emitting elements bonded to the circuit board.

According to another embodiment of the present disclosure, a method of transferring light emitting elements is provided. The method includes: placing a transfer member ledger having a protective film on a support member; cutting the transfer member ledger to a size of a transfer unit to form transfer members and forming an incision groove in the protective film to define a folding area and a transfer area in each of the transfer members; picking up and vertically and horizontally inverting a plurality of transfer members by using an inversion member; folding a transfer member of the folding area about the incision groove by using a clamp of a folding member and fixing the folded transfer member of the folding area; lifting the transfer member folded by the clamp by adsorbing the transfer member of the transfer area and fixing the clamp using a transfer head; peeling off the protective film from the transfer area; detaching light emitting elements from a donor substrate by attaching the light emitting elements to the transfer member of the transfer area by using the transfer head; detaching the clamp from a folding portion and fixing the clamp to the folding member; and aligning the light emitting elements on a circuit board by using the transfer head and detaching the transfer member from the transfer head.

The method may further include: bonding the light emitting elements, which are attached to the transfer member, onto the circuit board; and peeling and removing the transfer member from the light emitting elements bonded to the circuit board by using the transfer head. Each of the transfer members may include a base layer and a stamp layer on a surface of the base layer, and the stamp layer may be made of an adhesive material.

The circuit board may include a flux applied to a surface thereof. The flux may be removed from the circuit board by a flux cleaning agent after the peeling and removing of the transfer member from the light emitting elements bonded to the circuit board.

The bonding of the light emitting elements onto the circuit board may include any one of eutectic bonding, soldering bonding, and anisotropic conductive film bonding.

### BRIEF DESCRIPTION OF THE DRAWINGS

These and/or other aspects and features will become apparent and more readily appreciated from the following description of embodiments of the present disclosure, taken in conjunction with the accompanying drawings in which:

FIG. 1 is a layout view of a display device according to an embodiment;

FIG. 2 illustrates an example of a pixel shown in FIG. 1;

FIG. 3 illustrates another example of a pixel shown in FIG. 1;

FIG. 4 is a cross-sectional view of an example of a display panel taken along the line A-A′ of FIG. 2;

FIG. 5 is a flowchart describing steps of a method of transferring light emitting elements by using an apparatus for transferring the light emitting elements;

FIG. 6 is a perspective view illustrating a method of providing a transfer member ledger in a roll-to-roll manner;

FIG. 7 is a perspective view illustrating a method of providing the transfer member ledger in a sheet manner;

FIG. 8 is a cross-sectional view of the transfer member ledger on a support member;

FIG. 9 is a schematic view illustrating a process of cutting the transfer member ledger to a size of a transfer unit;

FIGS. 10 and 11 are schematic views illustrating transfer members inverted by an inversion member;

FIGS. 12 through 17 are schematic views illustrating an apparatus for transferring light emitting elements;

FIG. 18 is a schematic view illustrating bonding of light emitting elements;

FIG. 19 is a schematic view illustrating removal of a transfer member;

FIG. 20 is a schematic view illustrating a circuit board on which light emitting elements are arranged;

FIG. 21 is an enlarged view of the area A in FIG. 20;

FIGS. 22 and 23 are schematic views illustrating transfer members inverted by a robot;

FIG. 24 is an enlarged view of the area B of FIG. 23;

FIGS. 25A through 25D illustrate an incision groove in a transfer member according to various embodiments;

FIGS. 26A through 26C are plan views illustrating a transfer member according to various embodiments;

FIG. 27 is a flowchart describing steps of a method of transferring light emitting elements by using an apparatus for transferring the light emitting elements;

FIG. 28 schematically illustrates the configuration of a folding member;

FIGS. 29 through 31 schematically illustrate an apparatus for transferring light emitting elements according to raising or lowering of a transfer head;

FIG. 32 is a schematic view illustrating peeling of a protective film of a transfer member;

FIG. 33 illustrates picking up of light emitting elements;

FIGS. 34 and 35 illustrate a clamp separation process;

FIGS. 36A through 36D are plan views of clamps according to various embodiments;

FIGS. 37A and 37B are plan views of clamps according to various embodiments; and

FIGS. 38A through 38C are cross-sectional views of clamps according to various embodiments.

### DETAILED DESCRIPTION

The embodiments will now be described more fully hereinafter with reference to the accompanying drawings. The embodiments described herein, and the present disclosure, may, however, be provided in different forms and should not be construed as limiting. Some parts, which are not associated with the description, may not be provided to better describe embodiments of the disclosure.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meanings such as “apart from” or “set aside from” or “offset from” and any other suitable equivalents as would be appreciated and understood by those of ordinary skill in the art. The terms “face” and “facing” may mean that a first object may directly or indirectly oppose a second object. When a third object intervenes or is interposed between a first and second object, the first and second objects may be understood as being indirectly opposed to one another, although still facing each other.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

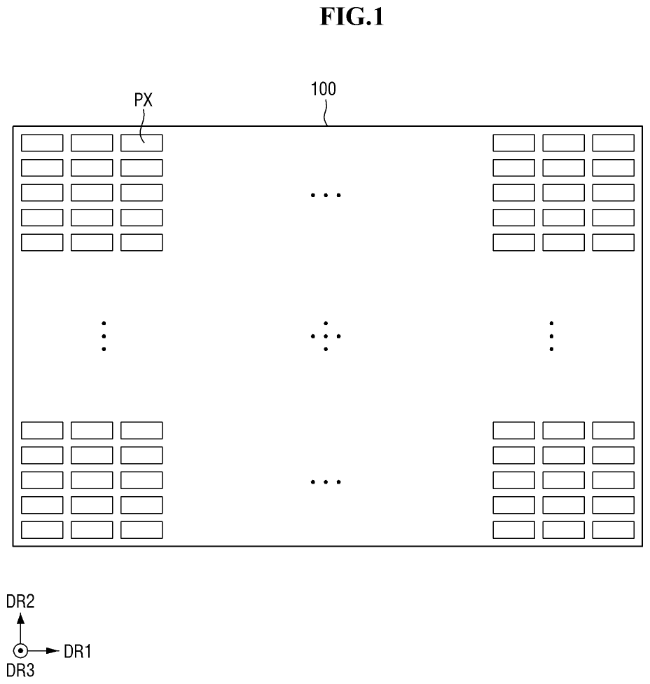

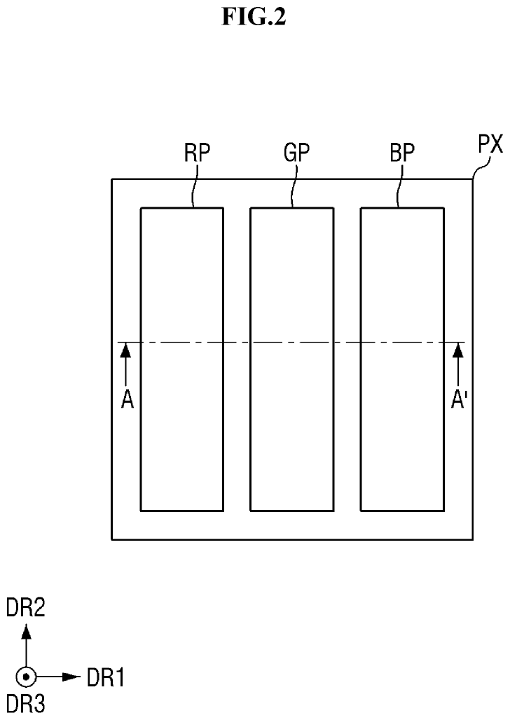

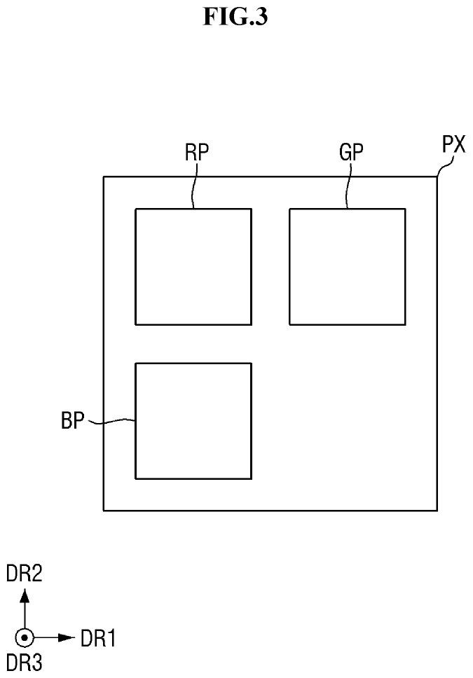

FIG. 1 is a layout view of a display device according to an embodiment. FIG. 2 illustrates an example of a pixel PX shown in FIG. 1. FIG. 3 illustrates another example of a pixel PX shown in FIG. 1.

Referring to FIGS. 1 through 3, the display device is a device for displaying moving images and/or still images. The display device may be used as a display screen in portable electronic devices, such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various larger products, such as televisions, notebook computers, monitors, billboards, and Internet of things (IoT) devices.

A display panel 100 may have a rectangular plane shape having long sides in a first direction DR1 and short sides in a second direction DR2 crossing (e.g., intersecting) the first direction DR1. Each corner at where a long side extending in the first direction DR1 meets a short side extending in the second direction DR2 may be rounded with a curvature (e.g., a predetermined curvature) or may be right-angled. The planar shape of the display panel 100 is not limited to a quadrilateral shape and may be, for example, another polygonal shape, a circular shape, or an oval shape. The display panel 100 may be flat, but the present disclosure is not limited thereto. For example, the display panel 100 may also have curved portions formed at left and right ends thereof and may have a constant curvature or a varying curvature. In some embodiments, the display panel 100 may be flexible so that it can be curved, bent, folded, or rolled.

The display panel 100 may include pixels PX, scan lines extending in the first direction DR1, and data lines extending in the second direction DR2 to display an image. The pixels PX may be arranged in the first direction DR1 and the second direction DR2 in a matrix arrangement.

Each of the pixels PX may include a plurality of subpixels RP, GP, and BP as illustrated in, for example, FIGS. 2 and 3. In FIGS. 2 and 3, each of the pixels PX includes three subpixels RP, GP, and BP, that is, a first subpixel RP, a second subpixel GP, and a third subpixel BP, but embodiments of the present disclosure are not limited thereto.

The first subpixel RP, the second subpixel GP, and the third subpixel BP may be connected to any one of the data lines and at least one of the scan lines.

Each of the first subpixel RP, the second subpixel GP, and the third subpixel BP may have a rectangular, square, or rhombic planar shape. For example, each of the first subpixel RP, the second subpixel GP, and the third subpixel BP may have a rectangular planar shape having short sides in the first direction DR1 and long sides in the second direction DR2 as illustrated in FIG. 2. In another embodiment, each of the first subpixel RP, the second subpixel GP, and the third subpixel BP may have a square or rhombic planar shape including sides having the same length in the first direction DR1 and the second direction DR2 as illustrated in FIG. 3.

As illustrated in FIG. 2, the first subpixel RP, the second subpixel GP, and the third subpixel BP may be arranged in (e.g., may be adjacent to each other in) the first direction DR1. In another embodiment, the first subpixel RP and any one of the second subpixel GP and the third subpixel BP may be arranged in the first direction DR1, and the first subpixel RP and the other one of the second subpixel GP and the third subpixel BP may be arranged in the second direction DR2. For example, as illustrated in FIG. 3, the first subpixel RP and the second subpixel GP may be arranged in the first direction DR1, and the first subpixel RP and the third subpixel BP may be arranged in the second direction DR2.

In another embodiment, the second subpixel GP and any one of the first subpixel RP and the third subpixel BP may be arranged in the first direction DR1, and the second subpixel GP and the other one of the first subpixel RP and the third subpixel BP may be arranged in the second direction DR2. In another embodiment, the third subpixel BP and any one of the first subpixel RP and the second subpixel GP may be arranged in the first direction DR1, and the third subpixel BP and the other one of the first subpixel RP and the second subpixel GP may be arranged in the second direction DR2.

The first subpixel RP may include a first light emitting element that emits (e.g., that is configured to emit) first light, the second subpixel GP may include a second light emitting element that emits (e.g., that is configured to emit) second light, and the third subpixel BP may include a third light emitting element that emits (e.g., that is configured to emit) third light. In one embodiment, the first light may be light in a red wavelength band, the second light may be light in a green wavelength band, and the third light may be light in a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm. However, embodiments of the present disclosure are not limited thereto.

Each of the first subpixel RP, the second subpixel GP, and the third subpixel BP may include an inorganic light emitting element having an inorganic semiconductor as (that operates or acts as) a light emitting element that emits (or is configured to emit) light. For example, the inorganic light emitting element may be a flip chip-type micro-light emitting diode, but embodiments of the present disclosure are not limited thereto.

As illustrated in FIGS. 2 and 3, the area of the first subpixel RP, the area of the second subpixel GP, and the area of the third subpixel BP may be substantially the same. However, embodiments of the present disclosure are not limited thereto. At least any one of the area of the first subpixel RP, the area of the second subpixel GP, and the area of the third subpixel BP may be different from another one. In some embodiments, any two of the area of the first subpixel RP, the area of the second subpixel GP, and the area of the third subpixel BP may be substantially the same, and the other one may be different from the two. In some embodiments, the area of the first subpixel RP, the area of the second subpixel GP, and the area of the third subpixel BP may be different from each other.

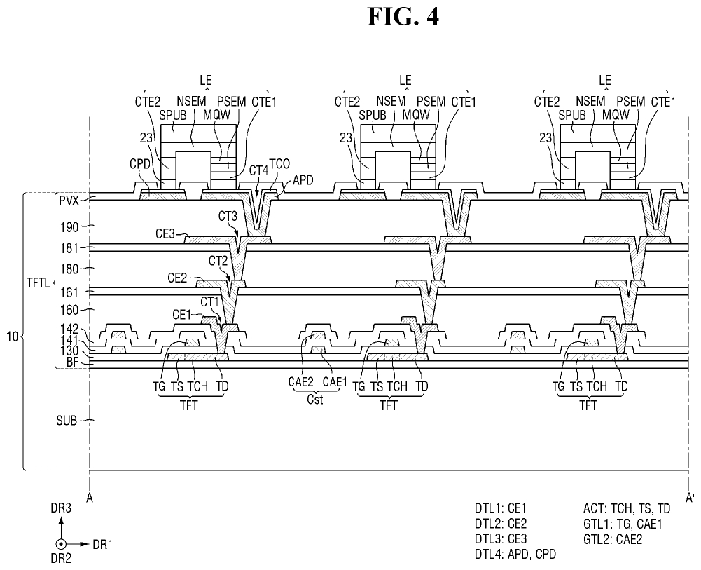

FIG. 4 is a cross-sectional view of an example of the display panel 100 taken along the line A-A′ of FIG. 2.

Referring to FIG. 4, the display panel 100 may include a thin-film transistor layer TFTL and light emitting elements LE disposed on a substrate SUB. The thin-film transistor layer TFTL may be a layer in which thin-film transistors TFT are formed.

The thin-film transistor layer TFTL includes an active layer ACT, a first gate layer GTL1, a second gate layer GTL2, a first data metal layer DTL1, a second data metal layer DTL2, a third data metal layer DTL3, and a fourth data metal layer DTL4. The thin-film transistor layer TFTL also includes a buffer layer BF, a gate insulating layer 130, a first interlayer insulating layer 141, a second interlayer insulating layer 142, a first planarization layer 160, a first insulating layer 161, a second planarization layer 180, and a second insulating layer 181.

The substrate SUB may be a base substrate or a base member for supporting the display device. The substrate SUB may be a rigid substrate made of glass, but embodiments of the present disclosure are not limited thereto. The substrate SUB may be a flexible substrate that can be bent, folded, rolled, or the like. In such an embodiment, the substrate SUB may include an insulating material, for example, polymer resin, such as polyimide (PI).

The buffer layer BF may be disposed on a surface of the substrate SUB. The buffer layer BF may be a layer for preventing penetration of air or moisture. The buffer layer BF may include a plurality of inorganic layers stacked alternately. For example, the buffer layer BF may have a multilayer structure in which one or more inorganic layers selected from a silicon nitride layer, a silicon oxynitride layer, a silicon oxide layer, a titanium oxide layer, and an aluminum oxide layer are alternately stacked. In some embodiments, the buffer layer BF may be omitted.

The active layer ACT may be disposed on the buffer layer BF. The active layer ACT may include a silicon semiconductor, such as polycrystalline silicon, monocrystalline silicon, low-temperature polycrystalline silicon, or amorphous silicon or may include an oxide semiconductor.

The active layer ACT may include a channel TCH, a first electrode TS, and a second electrode TD for each thin-film transistor TFT. The channel TCH of each thin-film transistor TFT may be a region overlapping a gate electrode TG of the corresponding thin-film transistor TFT in a third direction DR3, which is a thickness direction of the substrate SUB. The first electrode TS of each thin-film transistor TFT may be disposed on (or at) a side of the channel TCH, and the second electrode TD may be disposed on (or at) another side (e.g., an opposite side) of the channel TCH. The first electrode TS and the second electrode TD of each thin-film transistor TFT may be regions not overlapping (e.g., offset from) the gate electrode TG in the third direction DR3. The first electrode TS and the second electrode TD of each thin-film transistor TFT may be regions formed to have conductivity by doping a silicon semiconductor or an oxide semiconductor with ions.

The gate insulating layer 130 may be disposed on the active layer ACT. The gate insulating layer 130 may be made of an inorganic layer, for example, a silicon nitride layer, a silicon oxynitride layer, a silicon oxide layer, a titanium oxide layer, or an aluminum oxide layer.

The first gate layer GTL1 may be disposed on the gate insulating layer 130. The first gate layer GTL1 may include the gate electrode TG of each thin-film transistor TFT and first capacitor electrodes CAE1. The first gate layer GTL1 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

The first interlayer insulating layer 141 may be disposed on the first gate layer GTL1. The first interlayer insulating layer 141 may be made of an inorganic layer, for example, a silicon nitride layer, a silicon oxynitride layer, a silicon oxide layer, a titanium oxide layer, or an aluminum oxide layer.

The second gate layer GTL2 may be disposed on the first interlayer insulating layer 141. The second gate layer GTL2 may include second capacitor electrodes CAE2. The second gate layer GTL2 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

The second interlayer insulating layer 142 may be disposed on the second gate layer GTL2. The second interlayer insulating layer 142 may be made of an inorganic layer, for example, a silicon nitride layer, a silicon oxynitride layer, a silicon oxide layer, a titanium oxide layer, or an aluminum oxide layer.

The first data metal layer DTL1 including first connection electrodes CE1 and a data line DL may be disposed on the second interlayer insulating layer 142. The first data metal layer DTL1 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

Each of the first connection electrodes CE1 may be connected to the first electrode TS or the second electrode TD of a corresponding thin-film transistor TFT through a first contact hole (e.g., a first contact opening) CT1 penetrating (or extending through) the first interlayer insulating layer 141 and the second interlayer insulating layer 142.

The first planarization layer 160 may be disposed on the first data metal layer DTL1 to flatten steps (e.g., height differences) due to the active layer ACT, the first gate layer GTL1, the second gate layer GTL2, and the first data metal layer DTL1. The first planarization layer 160 may be made of an organic layer, such as acryl resin, epoxy resin, phenolic resin, polyamide resin, or polyimide resin.

The second data metal layer DTL2 may be disposed on the first planarization layer 160. The second data metal layer DTL2 may include second connection electrodes CE2. Each of the second connection electrodes CE2 may be connected to a corresponding first connection electrode CE1 through a second contact hole (e.g., a second contact opening) CT2 penetrating the first insulating layer 161 and the first planarization layer 160. The second data metal layer DTL2 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

The second planarization layer 180 may be disposed on the second data metal layer DTL2. The second planarization layer 180 may be made of an organic layer, such as acryl resin, epoxy resin, phenolic resin, polyamide resin, or polyimide resin.

The third data metal layer DTL3 may be disposed on the second planarization layer 180. The third data metal layer DTL3 may include third connection electrodes CE3. Each of the third connection electrodes CE3 may be connected to a corresponding second connection electrode CE2 through a third contact hole (e.g., a third contact opening) CT3 penetrating (or extending through) the second insulating layer 181 and the second planarization layer 180. The third data metal layer DTL3 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

A third planarization layer 190 may be disposed on the third data metal layer DTL3. The third planarization layer 190 may be made of an organic layer, such as acryl resin, epoxy resin, phenolic resin, polyamide resin, or polyimide resin.

The fourth data metal layer DTL4 may be disposed on the third planarization layer 190. The fourth data metal layer DTL4 may include anode pad electrodes APD and cathode pad electrodes CPD. Each of the anode pad electrodes APD may be connected to a corresponding third connection electrode CE3 through a fourth contact hole (e.g., a fourth contact opening) CT4 penetrating (or extending through) the third planarization layer 190. The cathode pad electrodes CPD may be supplied with a first power supply voltage, which is a low potential voltage. The fourth data metal layer DTL4 may be a single layer or may have a multilayer structure including any one or more of molybdenum (Mo), aluminum (Al), chromium (Cr), gold (Au), titanium (Ti), nickel (Ni), neodymium (Nd), copper (Cu), and alloys thereof.

A transparent conductive layer TCO may be disposed on each of the anode pad electrodes APD and the cathode pad electrodes CPD to increase adhesion to a first contact electrode CTE1 and a second contact electrode CTE2 of each of the light emitting elements LE. The transparent conductive layer TCO may be made of a transparent conductive oxide, such as indium tin oxide (ITO) or indium zinc oxide (IZO).

A passivation layer PVX may be disposed on the anode pad electrodes APD and the cathode pad electrodes CPD. The passivation layer PVX may cover edges of the anode pad electrodes APD and the cathode pad electrodes CPD. The passivation layer PVX may be made of an inorganic layer, for example, a silicon nitride layer, a silicon oxynitride layer, a silicon oxide layer, a titanium oxide layer, or an aluminum oxide layer. In another embodiment, the passivation layer PVX may be omitted.

Each of the light emitting elements LE is illustrated as a flip chip-type micro-light emitting diode in which the first contact electrode CTE1 and the second contact electrode CTE2 face the anode pad electrode APD and the cathode pad electrode CPD. However, embodiments of the present disclosure are not limited thereto. Each of the light emitting elements LE may be an inorganic light emitting element made of an inorganic material. such as GaN. The light emitting elements LE may have a length in a range of several to hundreds μm in each of the first direction DR1, the second direction DR2, and the third direction DR3. For example, the light emitting elements LE may have a length in a range of about 100 μm or less in each of the first direction DR1, the second direction DR2, and the third direction DR3.

The light emitting elements LE may be grown on a semiconductor substrate, such as a silicon wafer. Each of the light emitting elements LE may be directly transferred from the silicon wafer onto an anode pad electrode APD and a cathode pad electrode CPD of the substrate SUB. In such an embodiment, the first contact electrode CTE1 and the anode pad electrode APD may be bonded to each other through a bonding process. In addition, the second contact electrode CTE2 and the cathode pad electrode CPD may be bonded to each other through a bonding process. The first contact electrode CTE1 and the anode pad electrode APD may be electrically connected to each other through a bonding electrode 23. In addition, the second contact electrode CTE2 and the cathode pad electrode CPD may be electrically connected to each other through the bonding electrode 23.

For example, the bonding electrode 23 may be disposed on a surface of each of the light emitting elements LE. The bonding electrode 23 may be a bonding material configured for pressure melt-bonding by using a laser. During the pressure melt-bonding, the bonding electrode 23 is melted with heat to melt-mix each light emitting element LE with the anode pad electrode APD and the cathode pad electrode CPD and is cooled and solidified by termination of the laser supply. While being cooled and solidified in a melted and mixed state, the bonding electrode 23 may maintain conductivity due to (or between) the light emitting element LE, the anode pad electrode APD, and the cathode pad electrode CPD. Accordingly, the bonding electrode 23 may electrically and physically connect the anode pad electrode APD and the cathode pad electrode CPD to each light emitting element LE. Therefore, the bonding electrode 23 may be disposed on the first contact electrode CTE1 and the second contact electrode CTE2 of each light emitting element LE.

The bonding electrode 23 may include, for example, Au, AuSn, PdIn, InSn, NiSn, Au—Au, AgIn, AgSn, Al, Ag, or carbon nanotubes (CNT). These materials may be used alone or in combination of two or more. Depending on the type of the bonding electrode 23, the bonding electrode 23 may be deposited on a pad electrode or may be formed on the pad electrode through various methods, such as screen printing.

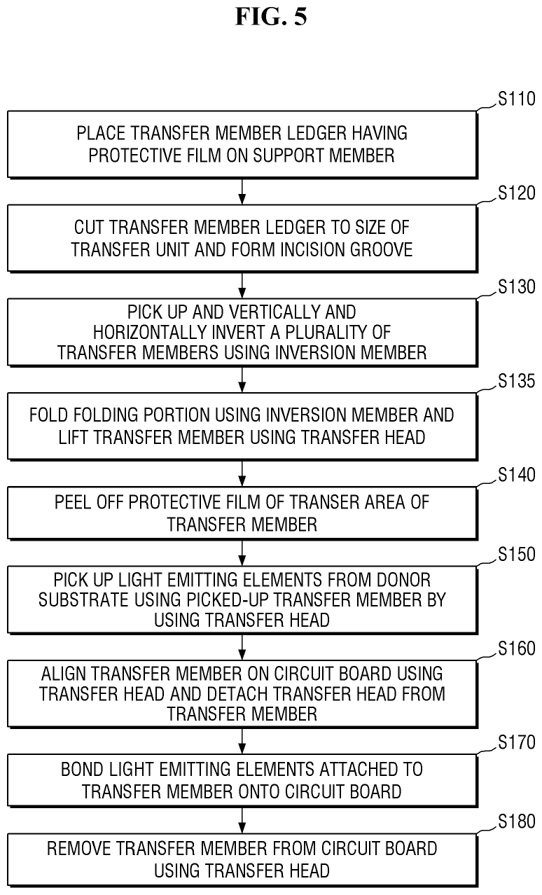

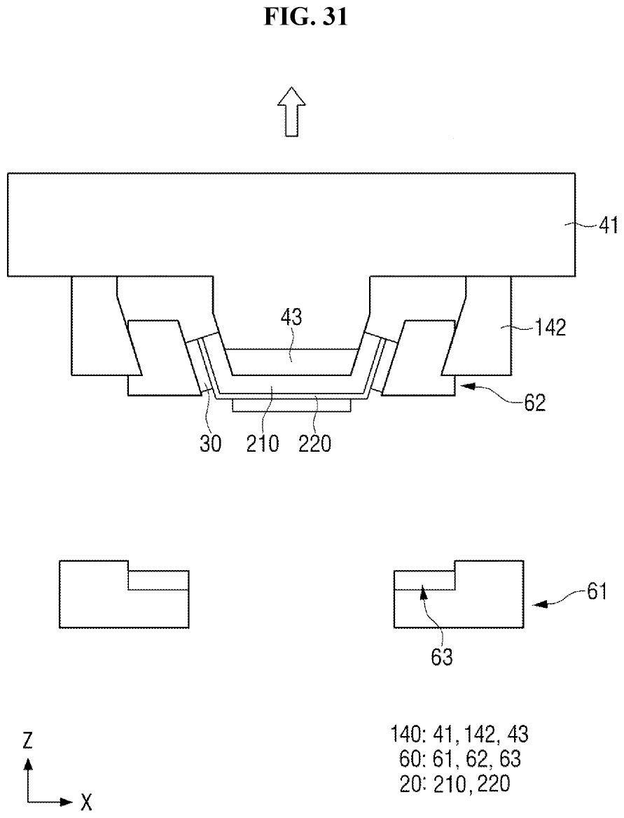

In other embodiments, each of the light emitting elements LE may be transferred onto the anode pad electrode APD and the cathode pad electrode CPD of the substrate SUB by using a transfer member. This will be described in more detail later with reference to FIGS. 5 through 38.

Each of the light emitting elements LE may be a light emitting structure including a base substrate SPUB, an n-type semiconductor NSEM, an active layer MQW, a p-type semiconductor PSEM, the first contact electrode CTE1, and the second contact electrode CTE2.

The base substrate SPUB may be a sapphire substrate, but embodiments of the present disclosure are not limited thereto.

The n-type semiconductor NSEM may be disposed on a surface of the base substrate SPUB. For example, the n-type semiconductor NSEM may be disposed on a lower surface of the base substrate SPUB. The n-type semiconductor NSEM may be made of GaN doped with an n conductivity-type dopant, such as Si, Ge, or Sn.

The active layer MQW may be disposed on a portion of a surface of the n-type semiconductor NSEM. The active layer MQW may include a material having a single or multiple quantum well structure. The multiple quantum well active layer MQW may have a structure in which a plurality of well layers and a plurality of barrier layers are alternately stacked. In one embodiment, the well layers may be made of InGaN, and the barrier layers may be made of GaN or AlGaN, but the present disclosure is not limited thereto. In another embodiment, the active layer MQW may have a structure in which a semiconductor material having a large band gap energy and a semiconductor material having a small band gap energy are alternately stacked or may include different group 3 to 5 semiconductor materials depending on the wavelength band of light to be emitted.

An apparatus and method for transferring light emitting elements according to an embodiment of the present disclosure will now be described with reference to FIGS. 5 through 26.

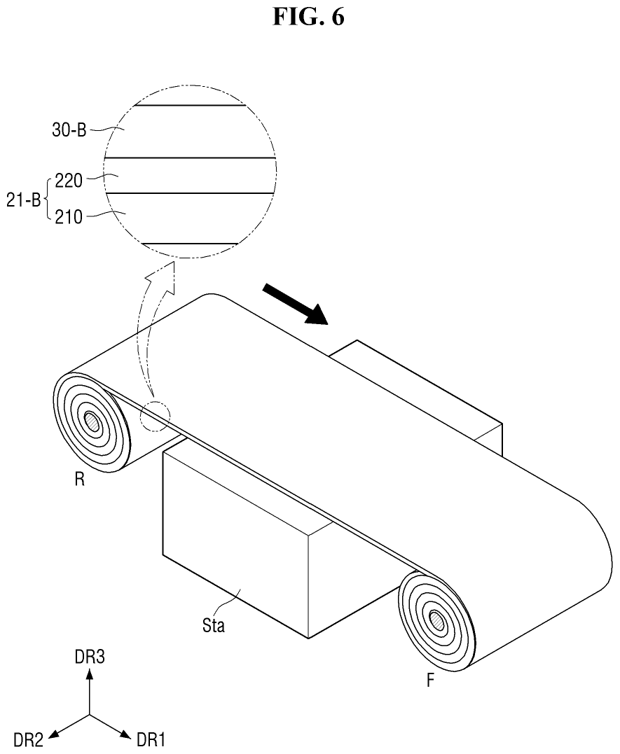

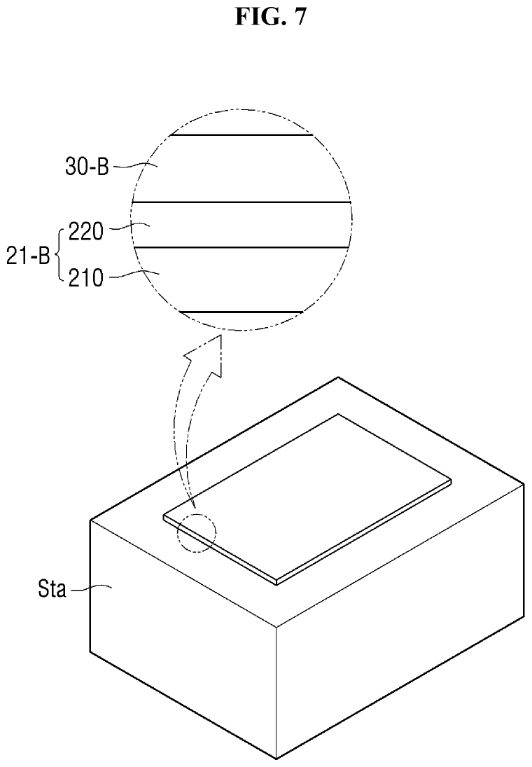

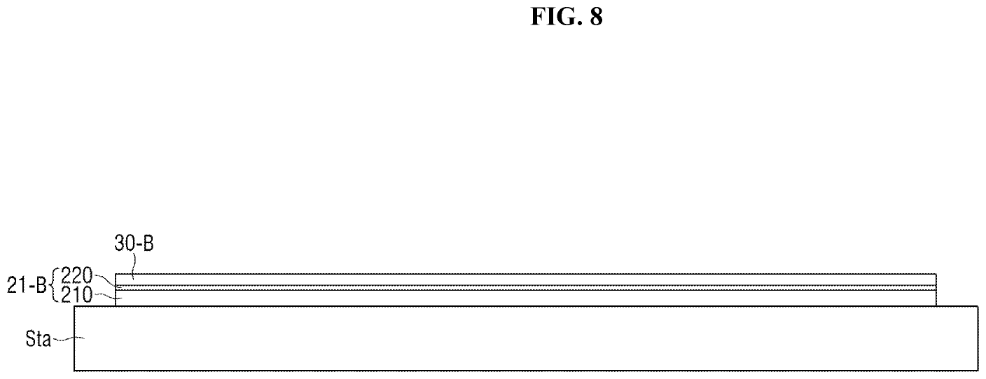

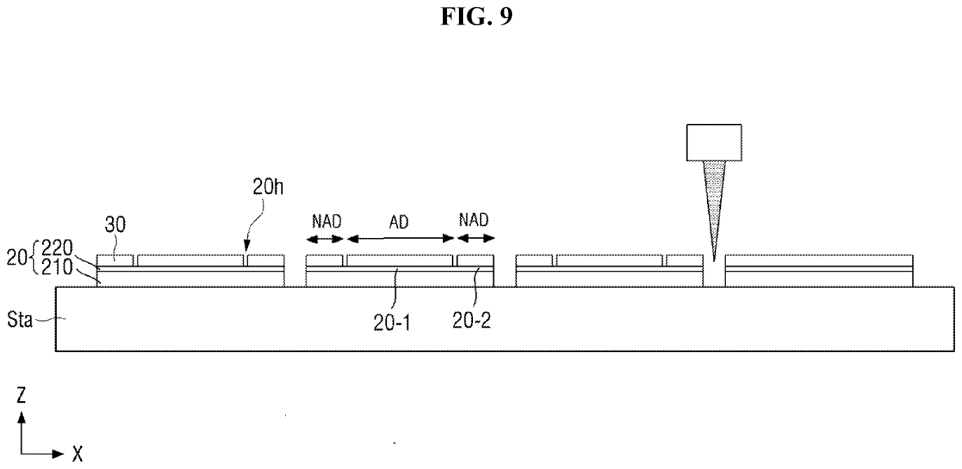

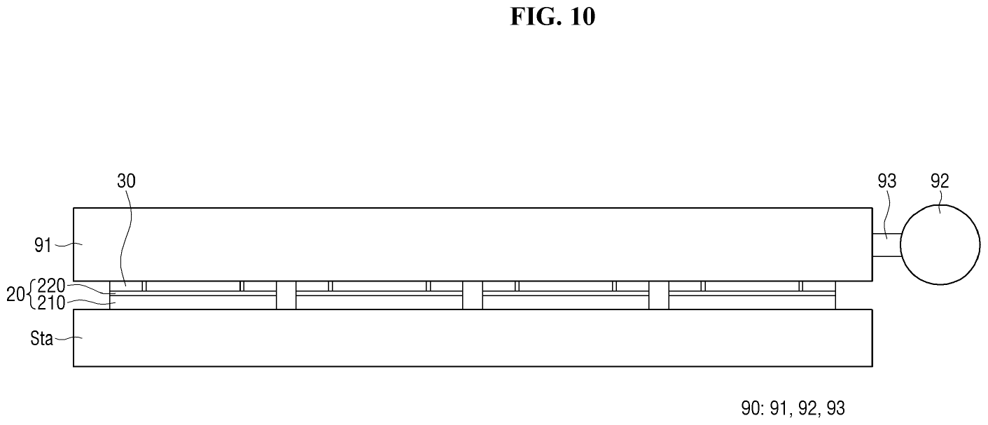

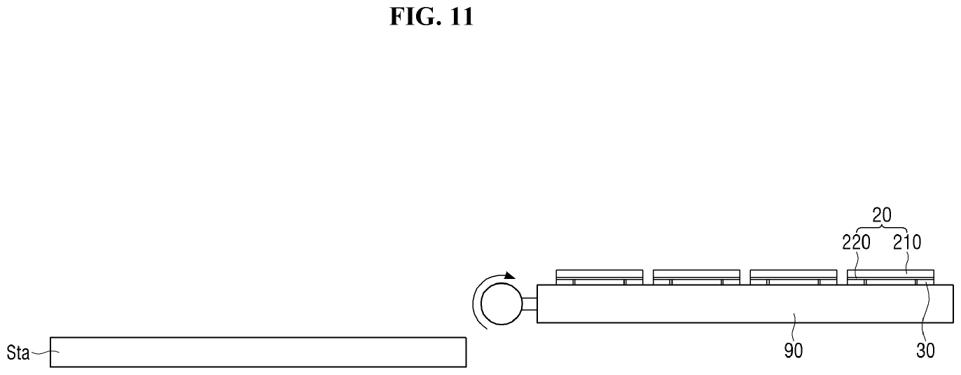

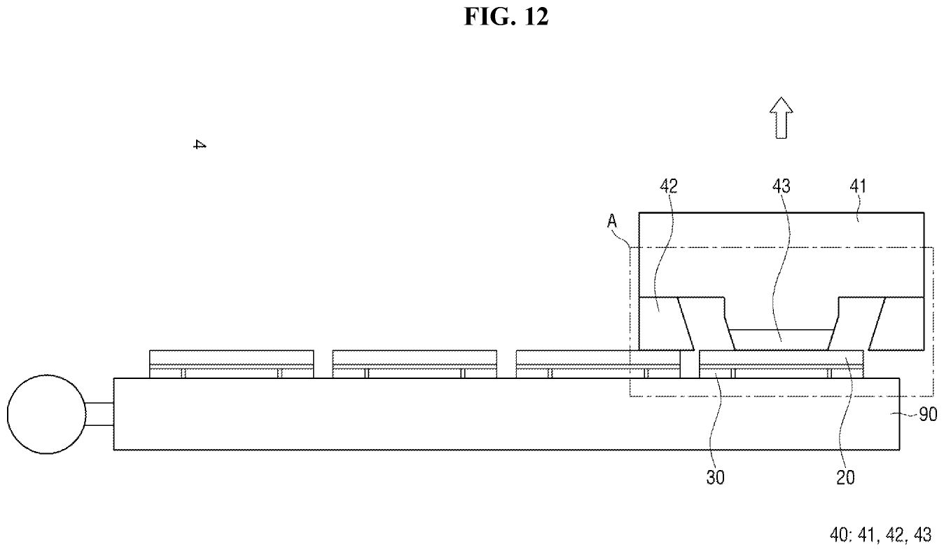

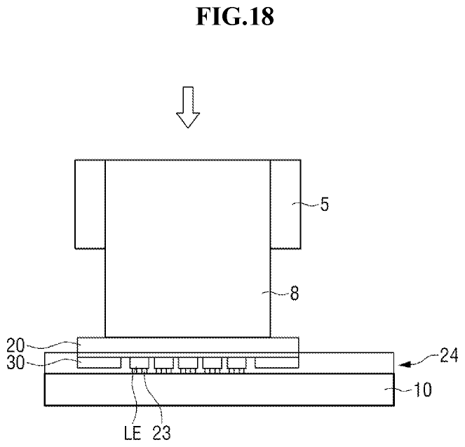

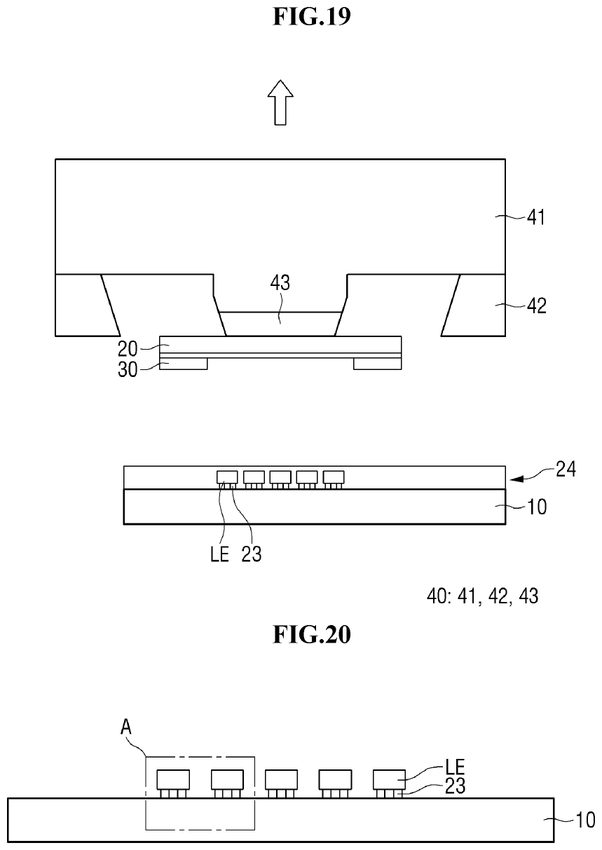

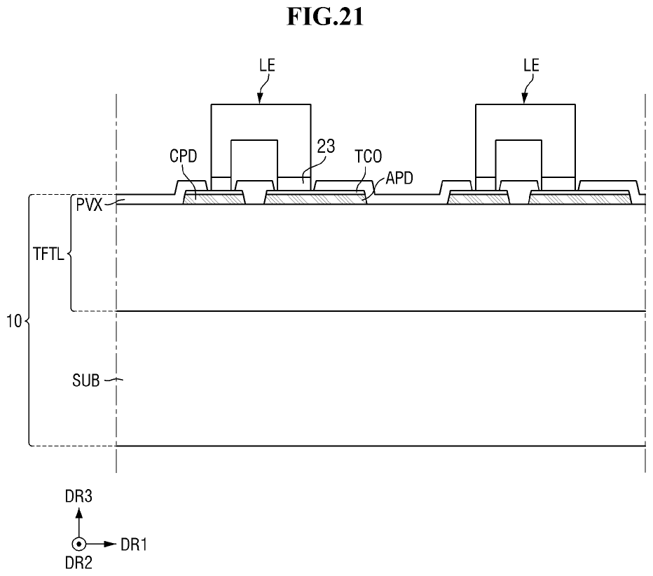

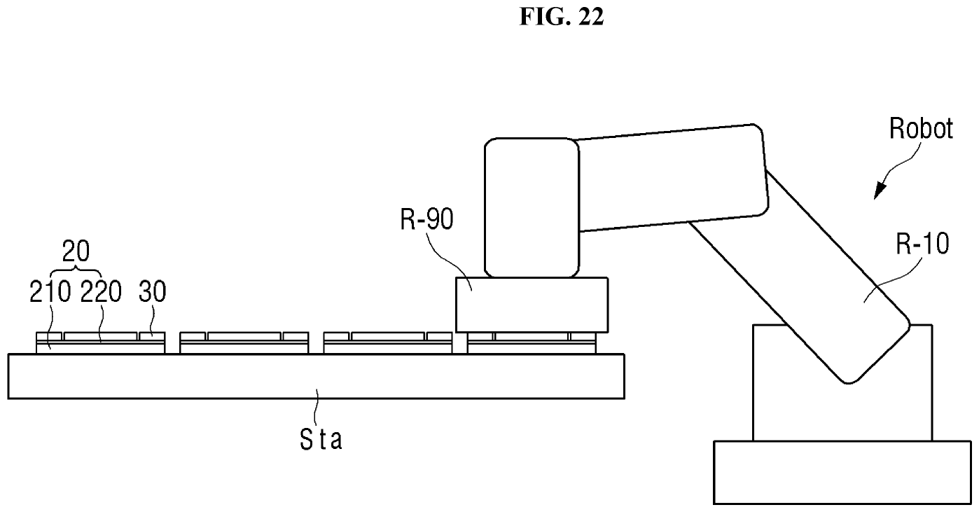

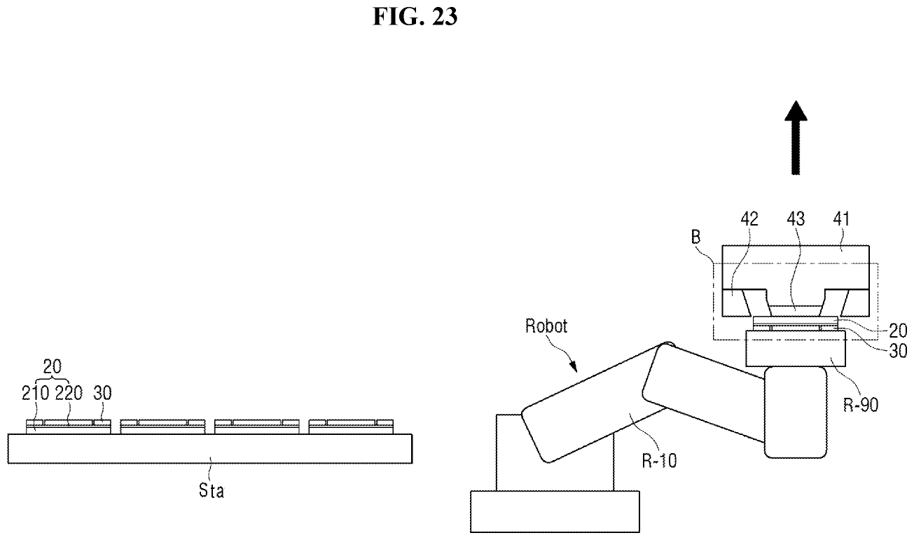

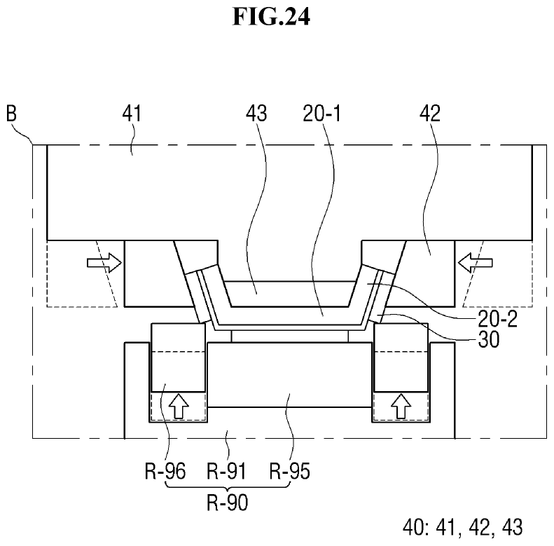

FIG. 5 is a flowchart describing steps of a method of transferring light emitting elements using an apparatus for transferring the light emitting elements described above. FIG. 6 is a perspective view illustrating a method of providing a transfer member ledger in a roll-to-roll manner. FIG. 7 is a perspective view illustrating a method of providing the transfer member ledger in a sheet manner. FIG. 8 is a schematic view of the transfer member ledger inverted on a support member. FIG. 9 is a schematic view illustrating a process of cutting the transfer member ledger to the size of a transfer unit. FIGS. 10 and 11 are schematic views illustrating transfer members inverted by an inversion member. FIGS. 12 through 17 are schematic views illustrating an apparatus for transferring light emitting elements. FIG. 18 is a schematic view illustrating bonding of light emitting elements. FIG. 19 is a schematic view illustrating removal of a transfer member. FIG. 20 is a schematic view illustrating a circuit board on which light emitting elements are arranged. FIG. 21 is an enlarged view of the area A in FIG. 20. FIGS. 22 and 23 are schematic views illustrating transfer members inverted by a robot. FIG. 24 is an enlarged view of the area B in FIG. 23.

Prior to the description of the method of transferring light emitting elements, an apparatus for transferring light emitting elements according to an embodiment will be briefly described.

Referring to FIGS. 9, 12, and 13, the apparatus for transferring light emitting elements according to the embodiment may include a transfer member 20, a protective film 30, an inversion member 90, and a transfer head 40.

The transfer member 20 includes a stamp layer 220 having a sticky or adhesive property and a base layer 210 disposed on a surface of the stamp layer 220.

The transfer member 20 may include a transfer portion 20-1 disposed in a transfer area AD and a folding portion 20-2 disposed in a folding area NAD in a plan view.

The protective film 30 is disposed on the other surface of the stamp layer 220 of the transfer member 20 to prevent contamination of the stamp layer 220.

The protective film 30 may have an incision groove 20h defining (or separating) the transfer area AD and the folding area NAD in a plan view.

The transfer area AD may be formed on the center side (e.g., the inner side) with the incision groove 20h as a boundary, and the folding area NAD may be formed on the edge side with the incision groove 20h as the boundary.

The inversion member 90 inverts the transfer member 20 vertically and horizontally.

The transfer head 40 has a head chuck 43 that is adsorbed to the base layer 210 of the transfer member 20 and enables the transfer member 20 to move vertically and horizontally (e.g., to move with the transfer head 40).

Each component will be described in detail with reference to the following drawings along with a transfer method using the components.

Referring to FIG. 5, a transfer member ledger having a protective film is placed on a support member (operation S110 in FIG. 5).

Here, the support member Sta supports a plurality of transfer members 20. The transfer members 20 may be aligned on the support member Sta.

As illustrated in FIG. 6, a transfer member ledger 21-B may be of a reel-to-reel type wound in a roll shape. When the transfer member ledger 21-B is provided in a reel-to-reel manner, it may be cut to a desired width for use. The transfer member ledger 21-B may include a base layer 210 and a stamp layer 220 disposed on a surface of the base layer 210 and may further include a protective film 30-B disposed on a surface of the stamp layer 220.

The base layer 210 may include, for example, glass or plastic. When the base layer 210 includes glass, the glass may be thin glass or ultra-thin glass. In other embodiments, the base layer 210 may be made of polyethylene terephthalate (PET), polyurethane (PU), polyimide (PI), polycarbonate (PC), polyethylene (PE), polypropylene (PP), polysulfone (PSF), polymethyl methacrylate (PMMA), triacetate cellulose (TAC), cycloolefin polymer (COP), or the like.

The stamp layer 220 is disposed on the surface of the base layer 210. The stamp layer 220 may be stuck or adhered to light emitting elements LE. The stamp layer 220 may be made of an adhesive or sticky material. Examples of the adhesive material may include an optical clear adhesive (OCA) and a pressure sensitive adhesive (PSA), and examples of the sticky material may include acrylic, urethane-based, and silicone-based sticky materials. The stamp layer 220 may be thinner than the base layer 210.

The protective film 30-B may be attached to a surface of the transfer member ledger 21-B, and the transfer head 40 may be adsorbed to the other surface of the transfer member ledger 21-B. Because the protective film 30-B is attached to a surface of the stamp layer 220 of the transfer member ledger 21-B, contaminants can be prevented from adhering to the stamp layer 220.

The protective film 30-B may include, for example, glass or plastic. When the protective film 30-B includes glass, the glass may be thin glass or ultra-thin glass. In addition, as illustrated in FIG. 7, the transfer member ledger 21-B may be a sheet type.

Referring to FIGS. 7 and 8, the transfer member ledger 21-B including the protective film 30-B is placed on the support member Sta such that the base layer 210, the stamp layer 220, and the protective film 30-B are sequentially stacked from the support member Sta. For example, the base layer 210 has a surface facing the support member Sta and another surface facing the stamp layer 220, and the stamp layer 220 has a surface facing the base layer 210 and another surface facing the protective film 30-B.

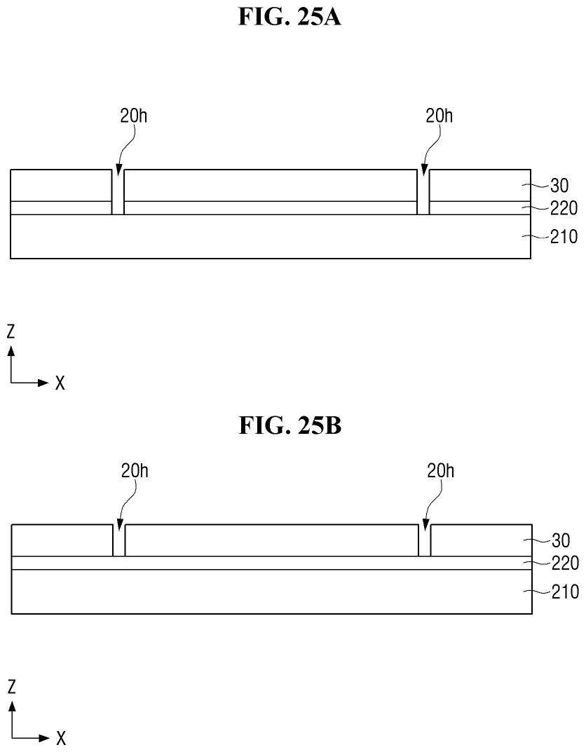

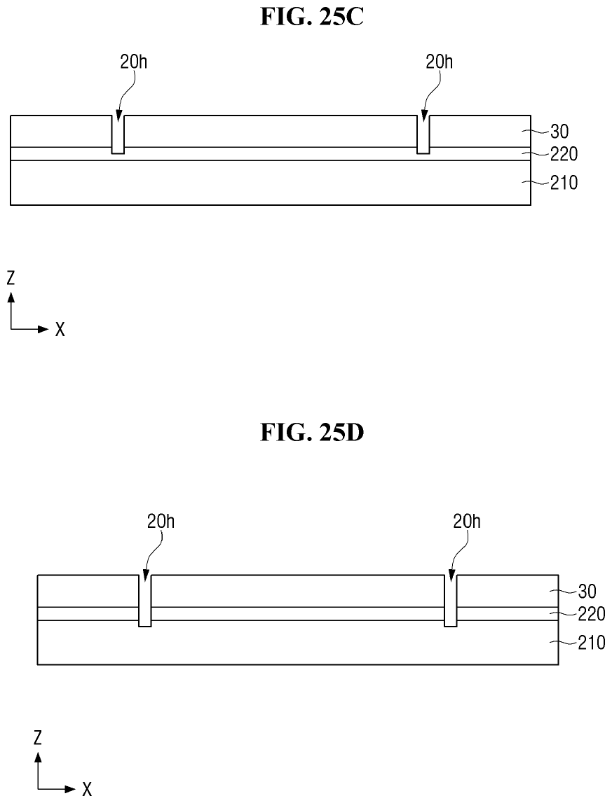

Next, referring to FIG. 9, the transfer member ledger 21-B including the protective film 30-B is cut to the size of a transfer unit on the support member Sta, and the incision groove 20h is formed in the transfer member ledger 21-B to form transfer members 20 corresponding to each transfer unit (operation S120 in FIG. 5). The transfer member 20 may have the transfer portion 20-1 and the folding portion 20-2. The transfer portion 20-1 may define the transfer area AD for transferring light emitting elements with the incision groove 20h as a boundary (e.g., an outer boundary), and the folding portion 20-2 may define the non-transfer area NAD disposed around (e.g., around a periphery of) the transfer area AD. The non-transfer area NAD may be disposed adjacent to the transfer area AD in a first direction (X-axis direction). The non-transfer area NAD may be folded about the incision groove 20h. The incision groove 20h has a depth equal to or greater than a thickness of at least the protective film 30 on the transfer member 20. The position, pattern, and depth of the incision groove 20h will be described with reference to FIGS. 25A through 25D later.

Cutting and incising may be performed by using a known cutting method, such as a mechanical method or a laser method. The transfer unit size refers to a size transferred to a circuit board at one time.

Next, a plurality of transfer members 20 are picked up and inverted vertically and horizontally by using the inversion member 90 (operation S130 in FIG. 5).

For example, referring to FIG. 10, the inversion member 90 may adsorb a surface of the protective film 30 attached to each of the transfer members 20 aligned on the support member Sta.

The inversion member 90 may include a stage 91, a rotation shaft 92, and a connector 93 connecting the stage 91 and the rotation shaft 92. The stage 91 may be rotated 180 degrees about the rotation shaft 92. The stage 91 may include a plurality of chucks. The chucks may be electrostatic chucks, adhesive chucks, vacuum chucks, or porous vacuum chucks. The stage 91 may adsorb a surface of the protective film 30 by using the chucks.

Referring to FIGS. 11 and 12, the inversion member 90 adsorbing the surface of the protective film 30 may rotate 180 degrees to vertically and horizontally to invert each transfer member 20 to which the protective film 30 is attached. Accordingly, the transfer members 20 may be placed in the order of the protective film 30, the stamp layer 220, and the base layer 210 sequentially from the inversion member 90.

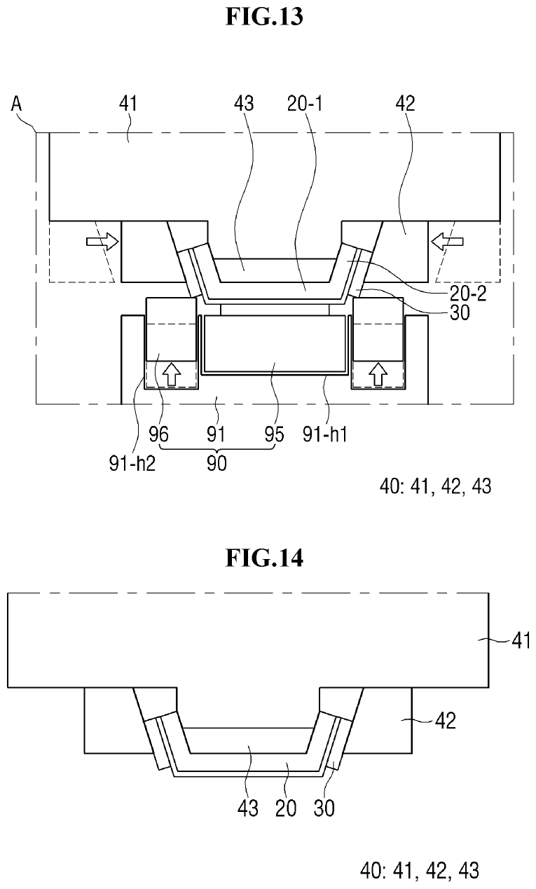

Prior to the description of a next operation, the inversion member 90 and the transfer head 40, which are devices for transferring light emitting elements, will be described with reference to FIGS. 12 and 13.

Referring to FIGS. 12 and 13, the inversion member 90 may further include the stage 91, a support chuck 95, and a vertical movement unit 96. The stage 91 may support a transfer member 20 and may have a plurality of grooves 91-h1 and 91-h2, and the support chuck 95 and the vertical movement unit 96 may be embedded in the grooves 91-h1 and 91-h2. The support chuck 95 may be disposed in a first groove 91-h1 formed in a central portion of the stage 91, and the vertical movement unit 96 may be disposed in a second groove 91-h2 neighboring the first groove 91-h1.

The vertical movement unit 96 may be disposed in the second groove 91-h2 and configured to move up and down. For example, a vertical driver for moving the vertical movement unit 96 up and down may be further included. The vertical driver may be provided in an area of the stage 91 and may include a hydraulic cylinder and a link unit. The hydraulic cylinder may provide a driving force to move the vertical movement unit 96. A hydraulic pump may be connected to the hydraulic cylinder. The hydraulic pump may further include a hydraulic handle for controlling the hydraulic pump. An additional member for changing the direction of the driving force according to the position of the hydraulic cylinder and the hydraulic pump may be further included. The above configuration for moving the vertical movement unit 96 up and down is only an example, and embodiments of the present disclosure are not limited thereto. Other known methods may be adopted.

When the vertical movement unit 96 is disposed in the second groove 91-h2, a plane of the stage 91 may be maintained flat (e.g., maintained in a flat orientation).

When a transfer member 20 is placed on the inversion member 90, the transfer portion 20-1 overlaps the support chuck 95 but does not overlap the vertical movement unit 96. The protective film 30 of the transfer portion 20-1 may be adsorbed by the support chuck 95. The folding portion 20-2 is placed to overlap the vertical movement unit 96.

The transfer head 40 may include a body 41, a clamp 42, and a head chuck 43.

The head chuck 43 may be disposed in a central portion of a surface of the body 41. The head chuck 43 may include any one of an electrostatic chuck, an adhesive chuck, a vacuum chuck, and a porous vacuum chuck. The area of the head chuck 43 providing adsorption may be equal to or smaller than the area of the transfer area AD of the transfer member 20.

The clamp 42 is disposed on the surface of the body 41 to be adjacent to the head chuck 43 and is movable in a horizontal direction. The clamp 42 may move toward or away from the head chuck 43 in the horizontal direction. The clamp 42 may cover at least a portion of an outer circumferential surface of the head chuck 43 and may be vertically symmetrical therewith. The transfer head 40 may include, for example, a guide rail for guiding the movement of the clamp 42 in the horizontal direction, but embodiments of the present disclosure are not limited thereto.

After the folding portion 20-2 of the non-transfer area NAD of the transfer member 20 is folded along the incision groove 20h by using the transfer head 40 and the inversion member 90 described above, the transfer member 20 is lifted (operation S135 in FIG. 5).

The head chuck 43 is placed to overlap the transfer area AD of the transfer member 20 and to not overlap the non-transfer area NAD. The head chuck 43 adsorbs a surface of the base layer 210 of the transfer member 20 by adsorption. Then, the vertical movement unit 96 rises in a third direction (e.g., the Z direction) to fold (e.g., to fold up) the folding portion 20-2 of the transfer member 20 about the incision groove 20h. Because the non-transfer area NAD of the transfer member 20 is disposed on the vertical movement unit 96 to overlap the vertical movement unit 96, when the vertical movement unit 96 rises, the non-transfer area NAD receives a force in an upwardly direction. On the other hand, the transfer area AD neighboring the non-transfer area NAD receives a fixing force by the adsorptive force of the support chuck 95. Therefore, the folding portion 20-2 of the transfer member 20 is folded up about the incision groove 20h so that the base layer 210 of the non-transfer area NAD is in contact with side surfaces of the head chuck 43. Accordingly, the transfer member 20 covers at least three surfaces of the head chuck 43. Next, the clamp 42 of the transfer head 40 moves toward the head chuck 43 in the horizontal direction to fix the folding portion 20-2 of the transfer member 20. Next, the support chuck 95 of the inversion member 90 detaches the transfer member 20 from the inversion member 90 by desorption.

While the transfer member 20 is fixed by the clamp 42, the transfer head 40 rises to lift the transfer member 20. Because the clamp 42 fixes the transfer member 20, the transfer member 20 may be strongly attached to the transfer head 40.

Next, as illustrated in FIG. 14, the protective film 30 of the transfer portion 20-1 of the transfer member 20 is peeled off (operation S140 in FIG. 5).

Because the adsorptive force between the head chuck 43 of the transfer head 40 and the transfer member 20 is greater than the sticking or adhesive force between the transfer member 20 and the protective film 30, the protective film 30 can be easily removed.

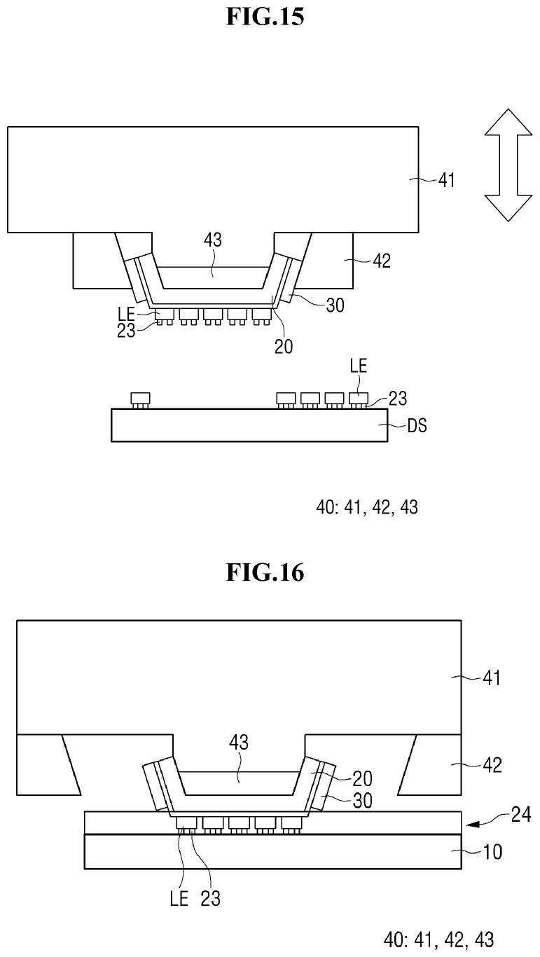

Referring to FIG. 15, the transfer head 40 picks up light emitting elements LE from a donor substrate Ds by using the picked-up transfer member 20 (operation S150 in FIG. 5).

As described with reference to FIG. 4, each of the light emitting elements LE includes a base substrate SPUB, an n-type semiconductor NSEM, an active layer MQW, a p-type semiconductor PSEM, a first contact electrode CTE1, and a second contact electrode CTE2. In addition, each of the light emitting elements LE may further include a bonding electrode 23. The bonding of the bonding electrode 23 will be described in more detail later with reference to FIG. 18.

First, the donor substrate Ds on which a plurality of light emitting elements LE are arranged is prepared. A sticky material may be applied to the donor substrate Ds. The donor substrate Ds and the light emitting elements LE may be adhered to each other by the sticky material.

The transfer head 40 transfers the picked-up transfer member 20 to the donor substrate Ds to adhere the light emitting elements LE to a surface of the transfer member 20. The light emitting elements LE are adhered to the stamp layer 220 of the transfer area AD of the transfer member 20.

Then, the transfer head 40 is raised in the third direction (Z direction) to separate the light emitting elements LE from the donor substrate Ds.

The transfer head 40 must pull in the third direction (e.g., the Z direction) with a tensile force greater than the sticking force (or adhesive force) between the donor substrate Ds and the light emitting elements LE. For the transfer head 40 to detach the light emitting elements LE from the donor substrate Ds through the transfer member 20, the adsorptive force between the transfer head 40 and the transfer member 20 should be greater than the sticking force between the donor substrate Ds and the light emitting elements LE. According to an embodiment, the transfer head 40 fixes the head chuck 43 and the transfer member 20 together by using the clamp 42. Therefore, even if the transfer head 40 applies a tensile force greater than the sticking force (or adhesive force) between the donor substrate Ds and the light emitting elements LE in the third direction (e.g., the Z direction), the head chuck 43 and the transfer member 20 may be strongly fixed to each other.

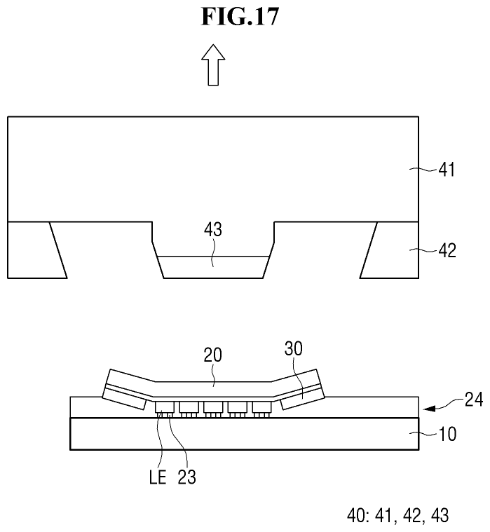

Referring to FIGS. 16 and 17, the transfer head 40 aligns the transfer member 20, to which the light emitting elements LE are attached, on a circuit board 10, and the transfer head 40 and the transfer member 20 are detached from each other (operation S160 in FIG. 5).

The circuit board 10 may be the substrate SUB including the thin-film transistor layer TFTL shown in FIG. 4.

A flux 24 having a thickness (e.g., a predetermined thickness) may be applied (e.g., may be pre-applied) to the circuit board 10. The flux 24 may be a material that facilitates bonding between the circuit board 10 and the bonding electrode 23 in a pressure melting process performed by using a laser. The flux 24 may include natural or synthetic resin and may be either oil-soluble or water-soluble. The flux 24 may be in liquid form or in gel form. After the pressure melting process is complete, the flux 24 is removed.

The flux 24 may be applied in a thickness smaller than that of the light emitting elements LE. However, in some areas, the thickness of the flux 24 may be equal to or greater than a height of the light emitting elements LE due to the arrangement of the light emitting elements LE.

After the transfer head 40 transfers the transfer member 20, to which the light emitting elements LE are attached, to a desired position, the transfer member 20 is detached from the transfer head 40 by desorption of the head chuck 43.

Referring to FIG. 18, the light emitting elements LE attached to the transfer member 20 are bonded onto the circuit board 10 (operation S170 in FIG. 5).

The light emitting elements LE to be bonded are placed on the circuit board 10, and the bonding electrode 23 is placed on a surface of each of the light emitting elements LE in contact with the circuit board 10. The transfer member 20 is placed on the other surface of each of the light emitting elements LE so that the circuit board 10, the light emitting elements LE, and the transfer member 20 overlap each other. A laser transmitting member 8 may be placed on the transfer member 20.

The laser transmitting member 8 may be made of a material that transmits a laser beam. The laser transmitting member 8 can be made of any beam transmitting material.

The laser transmitting member 8 may be made of any one of, for example, quartz, sapphire, fused silica glass, and diamond. However, physical properties of the laser transmitting member 8 made of quartz are different from physical properties of the laser transmitting member 8 made of sapphire. For example, when a 980 nm laser beam is irradiated, the transmittance of the laser transmitting member 8 made of quartz may be in a range of about 85 to about 99% while the transmittance of the laser transmitting member 8 made of sapphire may be in a range of about 80 to about 90%. A thin-film coating layer may be formed on a bottom surface of the laser transmitting member 8 made of quartz to prevent damage to and improve durability of the laser transmitting member 8 made of quartz. The thin-film coating layer may be formed on the bottom surface of the laser transmitting member 8 by conventional optical coating, such as dielectric coating, SiC coating, or metallic material coating.

An upper pressing member 5 may be connected to the laser transmitting member 8. The upper pressing member 5 may apply pressure in a direction. For example, the upper pressing member 5 may apply pressure in a direction in the third direction (e.g., the Z direction). Accordingly, the laser transmitting member 8 connected to the upper pressing member 5 may press the transfer member 20 in the direction in the third direction (e.g., the Z direction).

A laser beam LS may be irradiated to the bonding electrode 23 while the transfer member 20 is being pressed by the laser transmitting member 8. Thus, the laser beam LS may reach the bonding electrode 23 after passing through the laser transmitting member 8 and the transfer member 20. Accordingly, the laser beam LS may apply heat to the bonding electrode 23 up to the melting temperature of the bonding electrode 23, thereby pressure melt-bonding the circuit board 10 and the bonding electrode 23. During the pressure melt-bonding, the bonding electrode 23 is melted with heat by irradiation of the laser beam LS to melt-mix each light emitting element LE with an anode pad electrode APD and a cathode pad electrode CPD and is cooled and solidified by termination of the laser supply. While being cooled and solidified in a melted and mixed state, the bonding electrode 23 may maintain conductivity due to the light emitting element LE, the anode pad electrode APD, and the cathode pad electrode CPD. Therefore, the bonding electrode 23 may electrically and physically connect the anode pad electrode APD and the cathode pad electrode CPD to each light emitting elements LE.

The operation of the upper pressing member 5 and the laser transmitting member 8 may be controlled through a control unit. For example, the control unit may control the operation of the laser transmitting member 8 by using (e.g., according to) data received from a pressure sensor and a height sensor. The control unit may receive data from the pressure sensor and may control the upper pressing member 5 to reach a target pressure. In addition, the control unit may receive data from the height sensor and may control the upper pressing member 5 and the laser transmitting member 8 to reach a target height.

Although eutectic bonding, in which a laser beam is irradiated to the bonding electrode 23 disposed at an end of each light emitting element LE to melt-bond the light emitting element LE to the circuit board 10, has been described, embodiments of the present disclosure are not limited thereto. Any one of known bonding methods may be employed, such as soldering bonding in which each light emitting element LE and the circuit board 10 are bonded together by melting solder balls between the light emitting element LE and the circuit board 10 or anisotropic conductive film (ACF) bonding in which each light emitting element LE and the circuit board 10 are bonded together by heating an anisotropic conductive film between the light emitting element LE and the circuit board 10.

Referring to FIG. 19, the transfer head 40 may remove the transfer member 20 from the circuit board 10 (operation S180 in FIG. 5).

Referring to FIG. 19, the transfer member 20 disposed on the circuit board 10 to which the light emitting elements LE are bonded is attached to the transfer head 40 and then pulled by the transfer head 40 from the circuit board 10 in the third direction (e.g., the Z-axis direction) with an attractive force greater than the adhesive force between the light emitting elements LE and the transfer member 20. Accordingly, the transfer member 20 is detached from the circuit board 10 to which the light emitting elements LE are bonded. The adhesive force between the light emitting elements LE and the circuit board 10 may be the highest, the attachment force between the transfer member 20 and the transfer head 40 may be the next highest, and the adhesive force between the light emitting elements LE and the transfer member 20 may be the lowest. Therefore, when a force is applied in the third direction (e.g., the Z direction) in a state in which the circuit board 10, the light emitting elements LE, the transfer member 20, and the transfer head 40 overlap each other in the third direction (e.g., the Z direction), the light emitting elements LE and the transfer member 20 having the lowest adhesive force therebetween may be detached from each other.

Next, referring to FIG. 20, the flux 24 on the circuit board 10 to which the light emitting elements LE are bonded is removed by using a flux cleaning agent. A known flux cleaning agent (e.g., a water-based flux cleaning agent) may be used as the flux cleaning agent. Examples of the flux cleaning agent may include, but are not limited to, CLEANTHROUGH 750HS and CLEANTHROUGH 750K of Kao Corporation and PINE ALPHA ST-100S of Arakawa Chemical Industries, Ltd.

The conditions under which the circuit board 10 is cleaned are not particularly limited. For example, the circuit board 10 may be cleaned with a cleaning agent at a temperature in a range of about 30° C. to about 50° C. for about 1 to about 5 minutes (e.g., for about 2 to about 4 minutes at about 40° C.).

Referring to FIG. 21, each light emitting element LE may contact the anode pad electrode APD and the cathode pad electrode CPD of the circuit board 10 through the bonding electrode 23. As described above with reference to FIG. 4, the first contact electrode CTE1 of each light emitting element LE may contact the anode pad electrode APD of the circuit board 10, and the second contact electrode CTE2 of each light emitting element LE may contact the cathode pad electrode CPD.

Although flip chip light emitting elements have been described herein, embodiments of the present disclosure are not limited thereto, and vertical light emitting elements may also be used.

As described above, according to an embodiment of the present disclosure, a disposable transfer member detachable from the transfer head 40 and having a larger area than the head chuck 43 is used. Therefore, a contaminant, such as flux, does not need to be attached to the transfer member.

In addition, because the transfer member is removed after a bonding process, the flux applied to the circuit board 10 is prevented from directly contacting the laser transmitting member 8, thereby preventing contamination of the laser transmitting member 8.

FIGS. 22 and 23 are schematic views for explaining a method of inverting a transfer member according to an embodiment. FIG. 24 is an enlarged view of the area B in FIG. 23.

The method of reversing the order in which the base layer 210, the stamp layer 220, and the protective film 30 are sequentially stacked on the support member Sta by using the inversion member 90 has been described above with reference to FIGS. 10 through 13.

Referring to FIGS. 22, 23, and 24, the order in which the base layer 210, the stamp layer 220, and the protective film 30 are stacked on the support member Sta may be reversed by an articulated robot having a plurality of joints instead of by the inversion member 90.

The articulated robot may include a body R-10 having multiple joints and an adsorption unit R-90 configured at a front end of the body R-10 to pick up a transfer member 20 accommodated on the support member Sta. The adsorption unit R-90 includes an adsorption chuck R-95 for adsorbing the transfer member 20 and a vertical movement unit R-96 for folding up the folding portion 20-2. Because the body R-10 of the articulated robot can employ known technology, a detailed description thereof will be omitted. The adsorption member unit R-90 including the adsorption chuck R-95 and the vertical movement unit R-96 is similar to the inversion member 90 described above with reference to FIG. 13, and thus, a detailed description thereof will be omitted.

While adsorbing a surface of the protective film 30 by using the adsorption chuck R-95, the articulated robot may rotate the protective film 30 by 180 degrees to vertically and horizontally invert the transfer member 20 to which the protective film 30 is attached. Accordingly, the protective film 30 may be disposed under the transfer member 20 to which the protective film 30 is attached, and the transfer member 20, that is, the stamp layer 220 and the base layer 210 may be sequentially positioned on the protective film 30.

The articulated robot may transfer the inverted transfer member 20, to which the protective film 30 is attached, to the position of the donor substrate Ds. In another embodiment, the support member Sta may move to the articulated robot to adsorb the transfer member 20 to which the protective film 30 is attached. Then, the same processes as those of FIGS. 14 through 21 may be performed.

FIGS. 25A through 25D illustrate the incision groove 20h of a transfer member 20 according to various embodiments.

Referring to FIGS. 25A through 25D, the transfer member 20 to which the protective film 30 is attached includes the incision groove 20h.

In FIGS. 25A through 25D, the transfer member 20 is formed by sequentially stacking the base layer 210, the stamp layer 220, and the protective film 30. The incision groove 20h is formed in the protective film 30 in the direction of (e.g., the direction toward) the base layer 210.

As illustrated in FIG. 25A, the incision groove 20h may be formed to penetrate (or cut) the protective film 30 and the stamp layer 220. The incision groove 20h may not be formed in the base layer 210.

As illustrated in FIG. 25B, the incision groove 20h may be formed to penetrate the protective film 30. The incision groove 20h may not be formed in the stamp layer 220 and the base layer 210.

As illustrated in FIG. 25C, the incision groove 20h may penetrate the protective film 30 and may be formed in a portion of (e.g., may partially penetrate) the stamp layer 220. The incision groove 20h may not be formed in the base layer 210. As illustrated in FIG. 25D, the incision groove 20h may penetrate the protective film 30 and the stamp layer 220 and may be formed in a portion of (e.g., may partially penetrate) the base layer 210.

As can be seen from FIGS. 25A through 25D, the incision groove 20h may be formed to penetrate at least the protective film 30 and may be formed in a portion of the transfer member 20. However, the incision groove 20h is not formed to penetrate the entire transfer member 20.

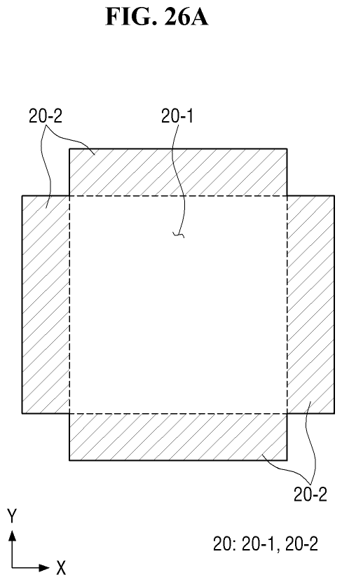

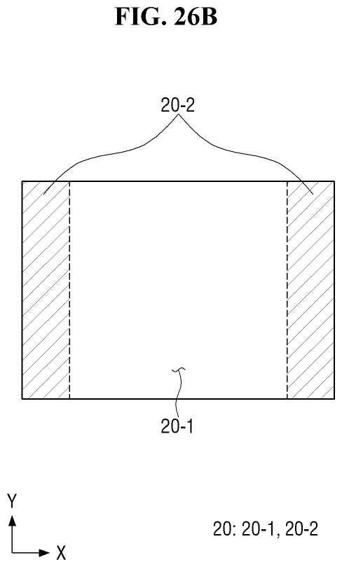

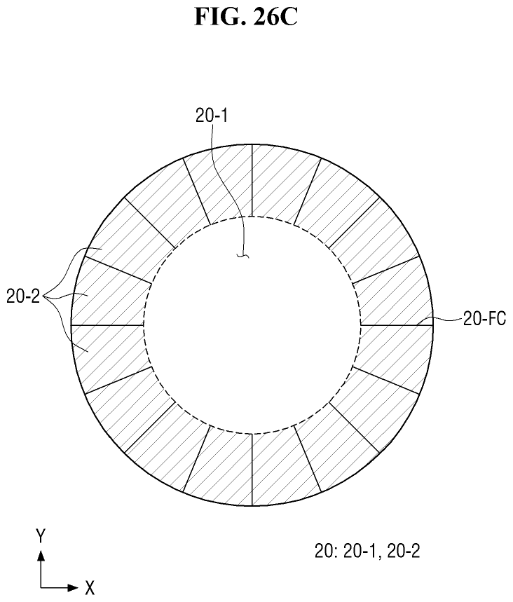

FIGS. 26A through 26C are plan views illustrating a transfer member 20 according to various embodiments.

Transfer members 20 shown in FIGS. 26A through 26C have a transfer portion 20-1 and a folding portion 20-2. In FIGS. 26A through 26C, a solid line indicates a full-cut state, and a dotted line indicates a half-cut state.

As illustrated in FIG. 26A, a transfer member 20 may include a folding portion 20-2 surrounding (e.g., surrounding in a plan view) a quadrilateral transfer portion 20-1. A boundary region between the transfer portion 20-1 and the folding portion 20-2 may be half-cut to form an incision groove 20h as described above with reference to FIGS. 25A through 25D.

As illustrated in FIG. 26B, a transfer member 20 may have a folding portion 20-2 disposed at both ends of a quadrilateral transfer portion 20-1. A boundary region between the transfer portion 20-1 and the folding portion 20-2 is half-cut to form an incision groove 20h as described above with reference to FIGS. 25A through 25D.

As illustrated in FIG. 26C, a transfer member 20 may have a folding portion 20-2 surrounding (e.g., surrounding in a plan view) a circular transfer portion 20-1. A plurality of notches 20-FC may be formed along the circumference of the transfer portion 20-1 to facilitate the folding of the circular folding portion 20-2. The notches 20-hc are formed at regular intervals.

A boundary region between the transfer portion 20-1 and the folding portion 20-2 is half-cut to form an incision groove 20h as described above with reference to FIGS. 25A through 25D.

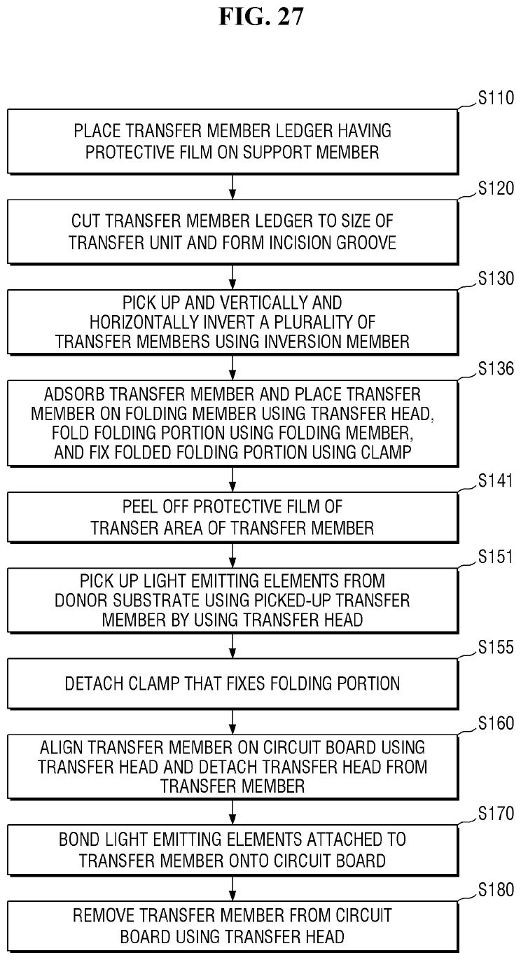

An apparatus and method for transferring light emitting elements according to an embodiment will now be described with reference to FIGS. 27 through 38.

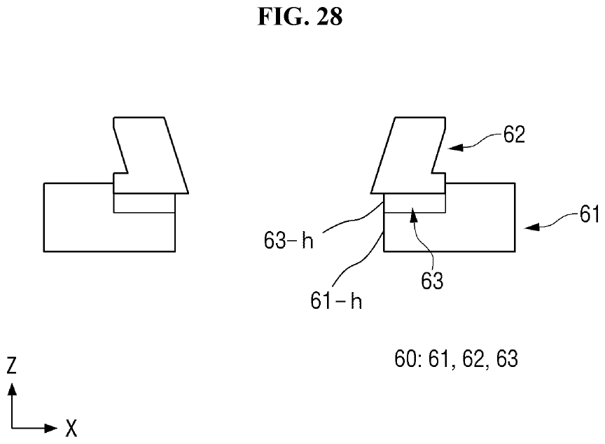

FIG. 27 is a flowchart describing steps of a method of transferring light emitting elements using an apparatus for transferring the light emitting elements. FIG. 28 schematically illustrates the configuration of a folding member 60.

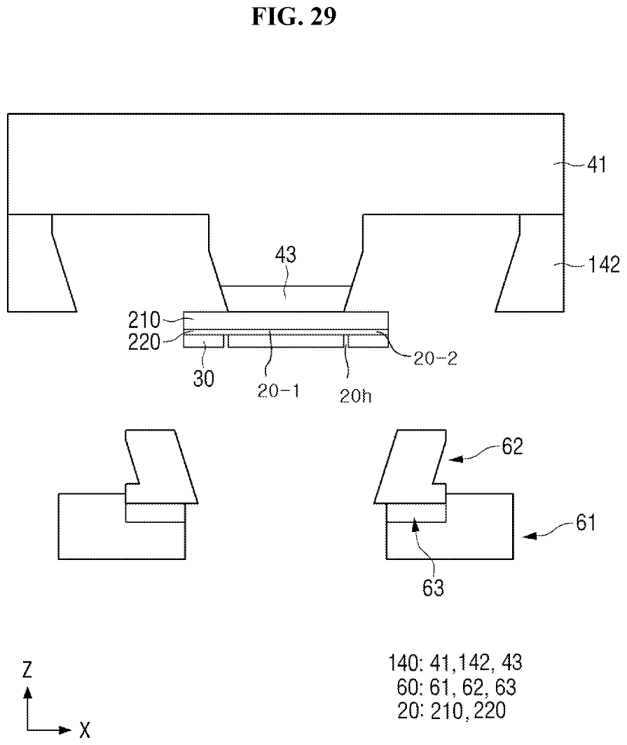

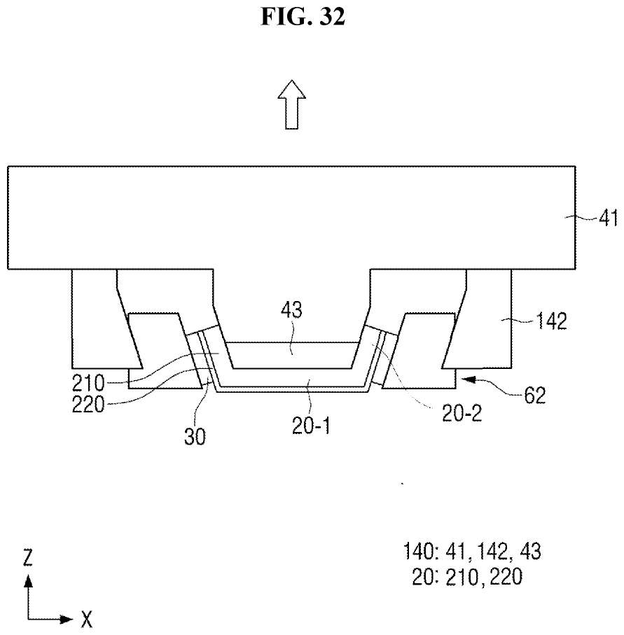

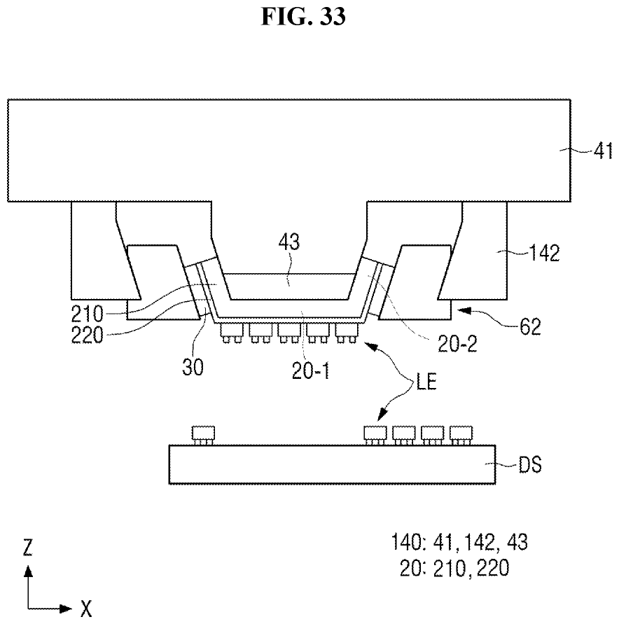

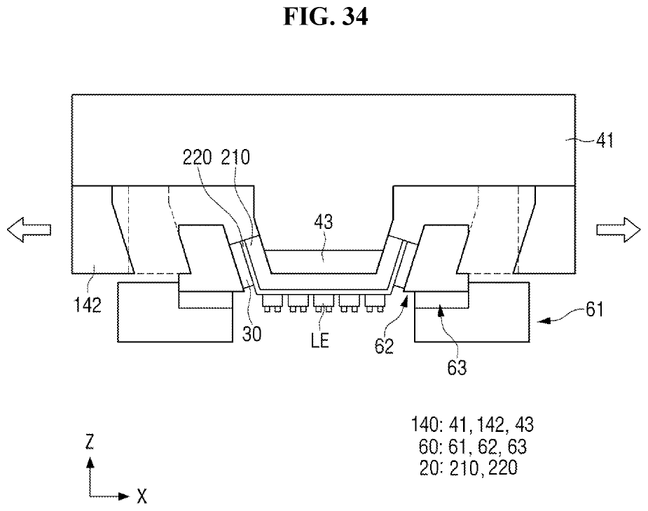

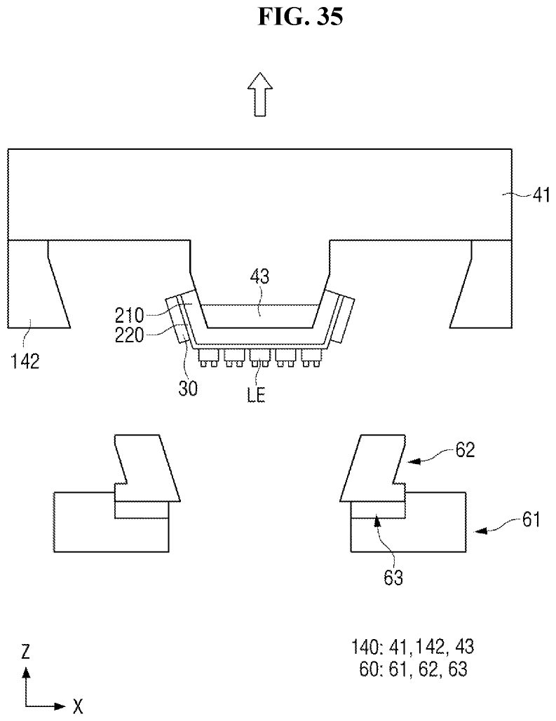

FIGS. 29 through 31 schematically illustrate an apparatus for transferring light emitting elements according to raising or lowering of a transfer head 140. FIG. 32 is a schematic view illustrating peeling of a protective film 30 of a transfer member 20. FIG. 33 illustrates picking up of light emitting elements LE. FIGS. 34 and 35 illustrate a clamp separation process.

An inversion member used in the present embodiment is different from the inversion member employed in the apparatus for transferring light emitting elements described above with reference to FIGS. 5 through 26 in that it does not include a vertical movement unit 96 and a support chuck 95, and a surface supporting a transfer member 20 is formed flat.

In addition, a folding portion of the transfer member 20 is folded and fixed by using a separate folding member not included in the apparatus for transferring light emitting elements described with reference to FIGS. 5 through 26.

Prior to the description of the method of transferring light emitting elements, an apparatus for transferring light emitting elements according to an embodiment will be described with reference to FIGS. 28 through 30.

Referring to FIGS. 28 through 30, the apparatus for transferring light emitting elements according to the embodiment may include the transfer member 20, the protective film 30, the transfer head 140, and the folding member 60.

The transfer member 20 includes a stamp layer 220 having a sticky or adhesive property and a base layer 210 disposed on a surface of the stamp layer 220.

The transfer member 20 may have a transfer portion 20-1 disposed in a transfer area AD and a folding portion 20-2 disposed in a folding area NAD in a plan view.

The protective film 30 is disposed on the other surface of the stamp layer 220 of the transfer member 20 to prevent contamination of the stamp layer 220.

The protective film 30 may have an incision groove 20h defining the transfer area AD and the folding area NAD in a plan view. The transfer area AD may be formed at the center side (or the inner side) from the incision groove 20h as a boundary, and the folding area NAD may be formed on the edge side (or the outer side) from the incision groove 20h as the boundary.

The transfer head 140 includes a body 41, a movable fixing portion 142, and a head chuck 43 and enables the transfer member 20 to move vertically and horizontally.

The movable fixing portion 142 may be formed such that a surface in contact with a clamp 62 when fixing the clamp 62, to be described later, is inclined. Because the movable fixing portion 142 has an inclined surface, it supports the clamp 62 when the clamp 62 for fixing the folding portion 20-2 moves up and down. In addition, because the surface in contact with the clamp 62 when the movable fixing portion 142 fixes the clamp 62, to be described later, is widened, the movable fixing portion 142 can stably fix the clamp 62. To this end, an outer surface of the clamp 62 may be formed to have the same inclination as the movable fixing portion 142.

The head chuck 43 may be disposed in a central portion of a surface of the body 41. The head chuck 43 may include any one of an electrostatic chuck, an adhesive chuck, a vacuum chuck, and a porous vacuum chuck. The area of the head chuck 43 may be equal to or smaller than the area of the transfer area AD of the transfer member 20.

The movable fixing portion 142 is disposed on the surface of the body 41 to be adjacent to the head chuck 43 and to be movable in the horizontal direction. The movable fixing portion 142 may move toward or away from the head chuck 43 in the horizontal direction. The movable fixing portion 142 may cover at least a portion of an outer circumferential surface of the head chuck 43 and may be vertically symmetrical therewith.

The movable fixing portion 142 may move between an edge of the body 41 and the head chuck 43 and may fix the folded folding portion 20-2.

The folding member 60 includes the detachable clamp 62.

The folding member 60 may include a clamp support portion 61, a clamp fixing portion 63, and the clamp 62 detachable from the clamp fixing portion 63.

The clamp support portion 61 may have a first groove (e.g. a central groove or central hole or opening) 61-h in its center and a second groove 63-h in a region adjacent to the first groove 61-h. The clamp fixing portion 63 is disposed in the second groove 63-h. The clamp 62 is disposed on the clamp fixing portion 63. The clamp 62 is detachably formed on the clamp fixing portion 63. For example, the clamp fixing portion 63 may have a chuck on a surface thereof. The chuck may be any one of an electrostatic chuck, an adhesive chuck, a vacuum chuck, and a porous vacuum chuck. In another embodiment, the clamp fixing portion 63 and the clamp 62 may include a magnet.

The clamp 62 may be attached to the clamp fixing portion 63 to guide the transfer member 20 to the first groove 61-h. The clamp 62 becomes narrower toward the bottom so that the folding portion 20-2 is folded when the transfer member 20 is mounted in the central groove 61h. The clamp 62 may be inclined closer to the center toward the bottom. For example, an opening in the clamp 62 is wider at the top than at the bottom. The clamp 62 keeps the folding portion 20-2 of the transfer member 20 folded by fixing the folding portion 20-2.

Each component will be described in detail with reference to the following drawings along with a transfer method using the components.

A transfer member ledger 21-B having a protective film 30-B is placed on a support member Sta (operation S110 in FIG. 27).

The transfer member ledger 21-B including the protective film 30-B is cut to the size of a transfer unit on the support member Sta, and an incision groove 20h is formed in a transfer member 20 of each transfer unit (operation S120 in FIG. 27).

Because operations S110 and S120 of in. 27 are similar to operations S110 through S130 in FIG. 5 described above, a redundant description thereof will be omitted.

Next, a plurality of transfer members 20 are picked up and inverted vertically and horizontally using an inversion member 90 (operation S130 in FIG. 27).

As described above with reference to FIG. 10, the inversion member 90 may adsorb a surface of the protective film 30 attached to each of the transfer members 20 aligned on the support member Sta. The inversion member 90 may include a stage 91, a rotation shaft 92, and a connector 93 connecting the stage 91 and the rotation shaft 92. The stage 91 may be rotated 180 degrees about the rotation shaft 92. The stage 91 may include a plurality of chucks. The chucks may be electrostatic chucks, adhesive chucks, vacuum chucks, or porous vacuum chucks.

Referring to FIG. 11, the inversion member 90 adsorbing the surface of the protective film 30 may rotate 180 degrees to vertically and horizontally invert each transfer member 20 to which the protective film 30 is attached. Accordingly, the transfer members 20 may be placed in the order of the protective film 30, the stamp layer 220, and the base layer 210 sequentially from the inversion member 90.

Next, the transfer head 140 adsorbs a transfer member 20 and places the transfer member 20 on the folding member 60. The folding member 60 folds the folding portion 20-2 of the transfer member 20 and fixes the folded folding portion 20-2 with the clamp 62 (operation S136 in FIG. 27).

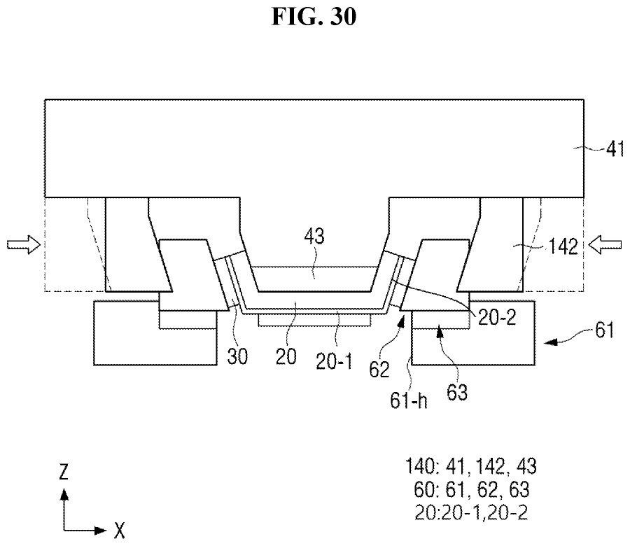

Referring to FIGS. 29 and 30, the transfer head 140 is placed such that the head chuck 43 overlaps the transfer portion 20-1 of the transfer member 20 and does not overlap the folding portion 20-2. The head chuck 43 adsorbs a surface of the base layer 210 of the transfer member 20 by adsorption. Then, the transfer head 140 moves vertically and horizontally to position the transfer member 20 on the folding member 60. The transfer head 140 moves vertically and horizontally to position the transfer portion 20-1 of the transfer member 20 above the first groove 61-h to overlap the first groove 61-h, which is the first hole in the folding member 60.

Next, the transfer head 140 moves downwardly to place the transfer portion 20-1 of the transfer member 20 in the first groove 61-h. A width of the first groove 61-h is smaller than a total width of the transfer member 20. Therefore, when the transfer portion 20-1 of the transfer member 20 is placed in the first groove 61-h, the folding portion 20-2 is folded by the clamp 62 along the incision groove 20h as an axis. Accordingly, the transfer member 20 covers at least three surfaces of the head chuck 43.

The movable fixing portion 142 moves toward the clamp 62 and presses the outside of the clamp 62 to firmly fix the clamp 62 to the head chuck 43.

Then, the clamp fixing portion 63 is detached from the clamp 62, and the transfer head 140 moves upwardly with the clamp 62 fixed thereto.

As illustrated in FIG. 32, the protective film 30 of the transfer portion 20-1 of the transfer member 20 is peeled off (operation S141 in FIG. 27).

Because an adsorptive force between the head chuck 43 of the transfer head 140 and the transfer member 20 is greater than a sticking or adhesive force between the transfer member 20 and the protective film 30, the protective film 30 can be easily removed.

As illustrated in FIG. 33, the transfer head 40 picks up light emitting elements LE from a donor substrate Ds by using the picked-up transfer member 20 (operation S151 in FIG. 27).

As described above with reference to FIG. 4, each of the light emitting elements LE may include a base substrate SPUB, an n-type semiconductor NSEM, an active layer MQW, a p-type semiconductor PSEM, a first contact electrode CTE1, and a second contact electrode CTE2. In addition, each of the light emitting elements LE may further include a bonding electrode 23.

First, the donor substrate Ds on which a plurality of light emitting elements LE are arranged is prepared. A sticky material may be applied to the donor substrate Ds. The donor substrate Ds and the light emitting elements LE may be adhered to each other by the sticky material.

The transfer head 140 transfers the picked-up transfer member 20 to the donor substrate Ds to adhere the light emitting elements LE to a surface of the transfer member 20. The light emitting elements LE are adhered to the stamp layer 220 of the transfer portion 20-1 of the transfer member 20.

Then, the transfer head 40 is raised in the third direction (e.g., the Z direction) to separate the light emitting elements LE from the donor substrate Ds.

The transfer head 40 must pull in the third direction (e.g., the Z direction) with a tensile force greater than the sticking force (or adhesive force) between the donor substrate Ds and the light emitting elements LE. For the transfer head 140 to detach the light emitting elements LE from the donor substrate Ds through the transfer member 20, the adsorptive force between the transfer head 140 and the transfer member 20 should be greater than the sticking force between the donor substrate Ds and the light emitting elements LE. According to an embodiment, the transfer head 140 fixes the head chuck 43 and the transfer member 20 together by using the clamp 62. Therefore, even if the transfer head 140 applies a tensile force greater than the sticking force (or adhesive force) between the donor substrate Ds and the light emitting elements LE in the third direction (e.g., the Z direction), the head chuck 43 and the transfer member 20 may be strongly fixed to each other.

As illustrated in FIGS. 34 and 35, the transfer head 140 moves to be above the folding member 60 to detach the clamp 42 fixing the folding portion 20-2 (operation S155 in FIG. 27).

The clamp 62 is placed on the clamp fixing portion 63, and the clamp fixing portion 63 attaches the clamp 62 thereto. Then, the movable fixing portion 142 moves toward the edge side of the body 41 and, thus, is separated from the clamp 62. Next, the transfer head 140 is raised in the third direction (e.g., the Z direction).

Next, the transfer head 140 aligns the transfer member 20 on a circuit board 10, and the transfer head 140 and the transfer member 20 are detached from each other (operation S160 in FIG. 27).

Next, the light emitting elements LE attached to the transfer member 20 are bonded onto the circuit board 10 (operation S170 in FIG. 27).

The transfer head 140 removes the transfer member 20 from the circuit board 10 (operation S180 in FIG. 27).

Because operations S160 through S180 of FIG. 27 are performed in the same manner as operations S160 through S180 described above with reference to FIGS. 16 through 21, a redundant description thereof will be omitted.

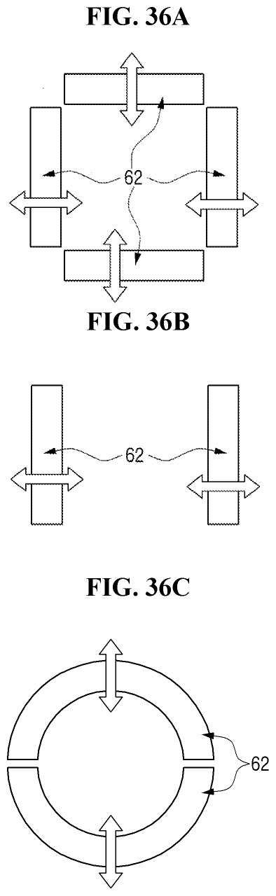

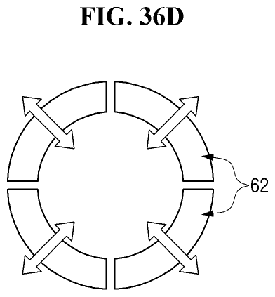

FIGS. 36A and 36B are plan views of clamps 62 according to various embodiments.

A clamp 62 is formed to correspond in size and shape to a folding portion 20-2 of a transfer member 20. The clamp 62 may be include a plurality of units. Each of the units may be formed to be movable on a plane.

Referring to FIGS. 26A and 36A, a transfer portion 20-1 may be formed in a quadrilateral shape, and the folding portion 20-2 may include a plurality of rectangular units disposed around the transfer portion 20-1. In such an embodiment, the clamp 62 may also include a plurality of rectangular units separated from each other.

Referring to FIGS. 26B and 36B, the transfer portion 20-1 may be formed in a quadrilateral shape, and the folding portion 20-2 may include two rectangular units disposed at both ends of the transfer portion 20-1. In such an embodiment, the clamp 62 may also include two rectangular units spaced apart from each other.

Referring to FIGS. 26C, 36C, and 36D, the transfer portion 20-1 may be formed in a circular shape, and the folding portion 20-2 may be formed in a donut (or ring) shape surrounding the transfer portion 20-1. In such an embodiment, the clamp 62 may also be formed in a donut shape but may include a plurality of units separated from each other.

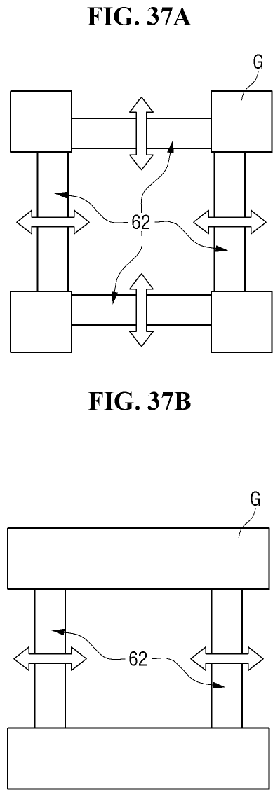

FIGS. 37A and 37B are plan views of clamps 62 according to various embodiments.

A clamp 62 is formed to correspond in size and shape to a folding portion 20-2 of a transfer member 20. The clamp 62 may include a plurality of units. The clamp 62 may further include a movement guide G. Each of the units may be formed to be movable within the movement guide G. For example, a guide rail may be fitted into the movement guide G so that the clamp 62 can slide.

Referring to FIGS. 26A and 37A, a transfer portion 20-1 may be formed in a quadrilateral shape, and the folding portion 20-2 may include a plurality of rectangular units disposed around the transfer portion 20-1. In such an embodiment, the clamp 62 may also include a plurality of rectangular units separated from each other. Each of the separated rectangular units may be fitted to the movement guide G. In such an embodiment, each of the separated rectangular units may be movable within the movement guide G.

Referring to FIGS. 26B and 37B, the transfer portion 20-1 may be formed in a quadrilateral shape, and the folding portion 20-2 may include two rectangular units disposed at both ends of the transfer portion 20-1. In such an embodiment, the clamp 62 may also include two rectangular units spaced apart from each other. Each of the separated rectangular units may be fitted to the movement guide G. In such an embodiment, each of the separated rectangular units may be movable within the movement guide G.

When the clamp 62 includes a plurality of units as illustrated in the embodiments of FIGS. 36A through 36D and each of the units is formed to be movable on a plane, the clamp 62 can be applied to various transfer members 20.

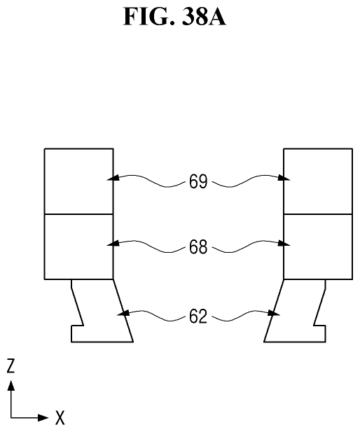

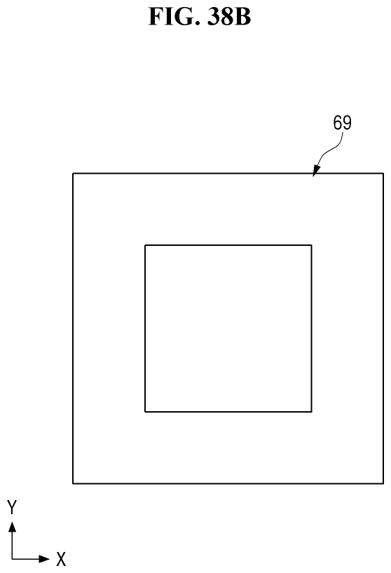

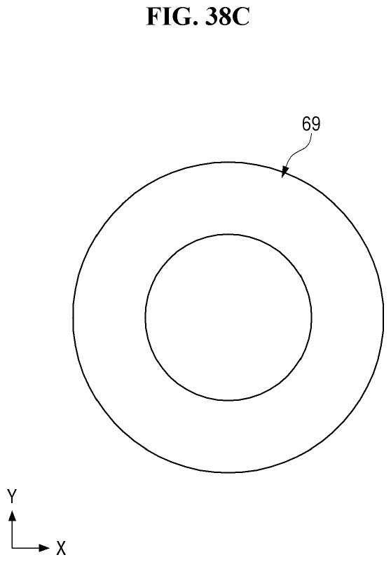

FIGS. 38A through 38C are cross-sectional views of clamps 62 according to various embodiments.

Referring to FIG. 38A, a clamp 62 is formed to correspond in size and shape to a folding portion 20-2 of a transfer member 20. The clamp 62 may further include a movement guide 68 and a frame 69. Each of a plurality of units may be formed to be movable within the movement guide 68. For example, a guide rail may be fitted into the movement guide 68 so that the clamp 62 can slide. The frame 69 may support the movement guide 68.

Referring to FIGS. 38B and 38C, the frame 69 may have a quadrilateral or circular shape. The frame 69 is formed to correspond in size and shape to the folding portion 20-2 of the transfer member 20.

As described in the above embodiments, a protective film is placed to face upwardly and is then cut. Therefore, a transfer process defect in which contaminants remain on a base layer may be avoided.

In addition, a transfer member is folded toward a head chuck of a transfer head. Therefore, the head chuck may not be contaminated by flux or the like.

In addition, because the transfer member is fixed by using a clamp, the transfer member may not be detached from the chuck when picking up light emitting elements. Therefore, production yield can be improved by reducing or minimizing the transfer process defect problem that can occur during a transfer process.

However, aspects and features of the present disclosure are not limited to those set forth herein. The above and other aspects and features of the present disclosure will become more apparent to one of daily skill in the art to which the present disclosure pertains by referencing the claims.

However, aspects and features of the disclosure are not limited to those set forth herein. The above and other aspects and features of the present disclosure will become more apparent to one of daily skill in the art to which the disclosure pertains by referencing the claims and their equivalents.

What is claimed is:

1. An apparatus for transferring light emitting elements, the apparatus comprising:
a transfer member comprising a stamp layer having an adhesive property and a base layer on a first surface of the stamp layer, the transfer member having a transfer portion, a folding portion, and an incision groove at a boundary between the transfer portion and the folding portion;
a protective film on a second surface of the stamp layer, the protective film having an incision groove defining a transfer area and a folding area;
an inversion member supporting the transfer member; and
a transfer head comprising a chuck configured to adsorb to the base layer and to move the transfer member vertically and horizontally,
wherein the transfer portion is at a center with respect to the incision groove, and the folding portion is at an outer side of the incision groove with respect to the transfer portion.

2. The apparatus of claim 1, wherein the inversion member comprises:
a support chuck configured to adsorb to the protective film at an area overlapping the transfer portion; and
a vertical movement unit neighboring the support chuck and configured to move up and down.

3. The apparatus of claim 2, wherein the transfer portion of the transfer member overlaps the support chuck, and the folding portion of the transfer member overlaps the vertical movement unit.

4. The apparatus of claim 3, wherein the folding portion is folded about the incision groove by rising of the vertical movement unit.

5. The apparatus of claim 4, wherein the transfer head comprises:
a body;
a head chuck in a center of the body and configured to adsorbed to the transfer portion of the transfer member; and
a clamp movable between an edge of the body and the head chuck and configured to fix the folding portion.

6. The apparatus of claim 5, wherein the head chuck has a surface equal to or smaller than the transfer area.

7. The apparatus of claim 5, wherein the folding portion of the transfer member covers at least three surfaces of the head chuck.

8. An apparatus for transferring light emitting elements, the apparatus comprising:
a transfer member comprising a stamp layer having a adhesive property and a base layer on a first surface of the stamp layer, the transfer member having an incision groove, a transfer portion at an inner side of the incision groove, and a folding portion at an outer side of the incision groove;
a protective film on a second surface of the stamp layer, the protective film having an incision groove defining a transfer area and a folding area;
a transfer head having a chuck configured to be adsorbed to the base layer and to move the transfer member vertically and horizontally; and
a folding member comprising a detachable clamp, the clamp being configured to maintain the folding portion of the transfer member folded by fixing the folding portion of the transfer member.

9. The apparatus of claim 8, wherein the folding member comprises:
a clamp support portion having a central groove in which the transfer portion of the transfer member is to be placed; and
a clamp fixing portion around the central groove,
wherein the clamp is detachably on the clamp fixing portion.

10. The apparatus of claim 9, wherein the folding member further comprises a movable support portion configured to move the clamp outwardly from the central groove according to a size of the transfer member.

11. The apparatus of claim 9, wherein the clamp is attached to the clamp fixing portion to guide the transfer member to the central groove and becomes narrower toward the bottom so that the folding portion is folded when the transfer member is placed in the central groove.

12. The apparatus of claim 9, wherein the transfer head comprises:
a body;
a head chuck in a center of the body and configured to be adsorbed to the transfer portion of the transfer member; and
a movable fixing portion movable between an edge of the body and the head chuck and configured to fix the folding portion.

13. The apparatus of claim 8, further comprising light emitting elements comprising an n-type semiconductor, an active layer, a p-type semiconductor, a first contact electrode, and a second contact electrode.

14. A method of transferring light emitting elements, the method comprising:
placing a transfer member ledger having a protective film on a support member;
cutting the transfer member ledger to a size of a transfer unit to form transfer members and forming an incision groove in the protective film to define a folding area and a transfer area in each of the transfer members;
vertically and horizontally inverting a plurality of transfer members by using an inversion member and folding a transfer member of the folding area;
fixing and lifting the folded transfer member by using a transfer head and peeling off the protective film of a transfer portion;
detaching light emitting elements from a donor substrate by attaching the light emitting elements to the transfer member of the transfer area and lifting the transfer member by using the transfer head; and
aligning the light emitting elements on a circuit board by using the transfer head and detaching the transfer member from the transfer head.

15. The method of claim 14, further comprising:
bonding the light emitting elements, which are attached to the transfer member, onto the circuit board; and
peeling and removing the transfer member from the light emitting elements bonded to the circuit board by using the transfer head.

16. The method of claim 14, wherein each of the transfer members comprises a base layer and a stamp layer on a surface of the base layer, and
wherein the stamp layer is made of an adhesive material.

17. The method of claim 16, wherein, in the placing of the transfer member ledger, the base layer, the stamp layer, and the protective film are sequentially on the support member.

18. The method of claim 17, wherein, in the placing of the transfer member ledger, the transfer member ledger is provided in a roll-to-roll type or a sheet type.

19. The method of claim 14, wherein the circuit board comprises a flux applied to a surface thereof.

20. The method of claim 19, wherein the flux is removed from the circuit board by a flux cleaning agent after the peeling and removing of the transfer member from the light emitting elements bonded to the circuit board.

21. The method of claim 14, wherein the bonding of the light emitting elements onto the circuit board comprises any one of eutectic bonding, soldering bonding, and anisotropic conductive film bonding.

22. A method of transferring light emitting elements, the method comprising:
placing a transfer member ledger having a protective film on a support member;
cutting the transfer member ledger to a size of a transfer unit to form transfer members and forming an incision groove in the protective film to define a folding area and a transfer area in each of the transfer members;
picking up and vertically and horizontally inverting a plurality of transfer members by using an inversion member;
folding a transfer member of the folding area about the incision groove by using a clamp of a folding member and fixing the folded transfer member of the folding area;
lifting the transfer member folded by the clamp by adsorbing the transfer member of the transfer area and fixing the clamp using a transfer head;
peeling off the protective film from the transfer area;
detaching light emitting elements from a donor substrate by attaching the light emitting elements to the transfer member of the transfer area by using the transfer head;
detaching the clamp from a folding portion and fixing the clamp to the folding member; and
aligning the light emitting elements on a circuit board by using the transfer head and detaching the transfer member from the transfer head.

23. The method of claim 22, further comprising:
bonding the light emitting elements, which are attached to the transfer member, onto the circuit board; and
peeling and removing the transfer member from the light emitting elements bonded to the circuit board by using the transfer head.

24. The method of claim 22, wherein each of the transfer members comprises a base layer and a stamp layer on a surface of the base layer, and
wherein the stamp layer is made of an adhesive material.

25. The method of claim 22, wherein the circuit board comprises a flux applied to a surface thereof.

26. The method of claim 25, wherein the flux is removed from the circuit board by a flux cleaning agent after the peeling and removing of the transfer member from the light emitting elements bonded to the circuit board.

27. The method of claim 22, wherein the bonding of the light emitting elements onto the circuit board comprises any one of eutectic bonding, soldering bonding, and anisotropic conductive film bonding.
